(19) United States
(12) Patent Application Publication
(10) Pub. No.: US 2023/0395510 A1
(43) Pub. Date: Dec. 7, 2023

(54) MICROELECTRONIC DEVICES WITH CONTACTS EXTENDING THROUGH METAL OXIDE REGIONS OF STEP TREADS, AND RELATED SYSTEMS AND METHODS

(71) Applicant: Micron Technology, Inc., Boise, ID (US)

(72) Inventors: Mithun Kumar Ramasahayam, Meridian, ID (US); Jordan D. Greenlee, Boise, ID (US); Harsh Narendrakumar Jain, Boise, ID (US); Jiewei Chen, Meridian, ID (US); Indra V. Chary, Boise, ID (US)

(21) Appl. No.: 17/812,141

(22) Filed: Jul. 12, 2022

Related U.S. Application Data
(60) Provisional application No. 63/365,690, filed on Jun. 1, 2022.

(51) Int. Cl. H01L 23/535; H01L 23/528; H01L 23/532; H01L 21/768

(52) U.S. Cl. CPC H01L 23/535; H01L 23/5283; H01L 23/53209; H01L 23/53242; H01L 23/53257; H01L 21/76805; H01L 21/76816; H01L 21/76895; H01L 21/76888

(57) ABSTRACT

Microelectronic devices include a stack with a vertically alternating sequence of insulative and conductive structures arranged in tiers. A staircased stadium within the stack comprises steps at different tier elevations of a group of the tiers. Treads of the steps are each provided by an upper surface area of one of the conductive structures within the group of the tiers and by an upper surface area of a metal oxide region extending through the one of the conductive structures. A pair of conductive contact structures extends to one of the steps. A first conductive contact structure of the pair terminates at the tread of the step, within the area of the conductive structure. A second conductive contact structure of the pair extends through the tread of the step, within the upper surface area of the metal oxide region. Related fabrication methods and electronic systems are also disclosed.

### CROSS-REFERENCE TO RELATED APPLICATION

This application claims the benefit under 35 U.S.C. § 119(e) of U.S. Provisional Patent Application Ser. No. 63/365,690, filed Jun. 1, 2022, the disclosure of which is hereby incorporated in its entirety herein by this reference.

### TECHNICAL FIELD

Embodiments of the disclosure relate to the field of microelectronic device design and fabrication. More particularly, the disclosure relates to microelectronic devices (e.g., memory devices, such as 3D NAND memory devices) with series of staircased stadiums formed in a tiered stack of conductive structures vertically alternating with insulative structures. The disclosure also relates to methods for forming such devices and to systems incorporating such devices.

### BACKGROUND

Memory devices provide data storage for electronic systems. A Flash memory device is one of various memory device types and has numerous uses in modern computers and other electrical devices. A conventional Flash memory device may include a memory array that has a large number of charge storage devices (e.g., memory cells, such as non-volatile memory cells) arranged in rows and columns. In a NAND architecture type of Flash memory, memory cells arranged in a column are coupled in series, and a first memory cell of the column is coupled to a data line (e.g., a bit line). In a “three-dimensional NAND” memory device (which may also be referred to herein as a “3D NAND” memory device), a type of vertical memory device, not only are the memory cells arranged in row and column fashion in a horizontal array, but tiers of the horizontal arrays are stacked over one another (e.g., as vertical strings of memory cells) to provide a “three-dimensional array” of the memory cells. The stack of tiers vertically alternate conductive materials with insulating (e.g., dielectric) materials. The conductive materials function as control gates for, e.g., access lines (e.g., word lines) of the memory cells. Vertical structures (e.g., pillars comprising channel structures and tunneling structures) extend along the vertical string of memory cells. A drain end of a string is adjacent one of the top and bottom of the vertical structure (e.g., pillar), while a source end of the string is adjacent the other of the top and bottom of the pillar. The drain end is operably connected to a bit line, while the source end is operably connected to a source structure (e.g., a source plate, a source line). A 3D NAND memory device also includes electrical connections between, e.g., access lines (e.g., word lines) and other conductive structures of the device so that the memory cells of the vertical strings can be selected for writing, reading, and erasing operations.

Some 3D NAND memory devices include so-called “staircase” structures having “steps” (or otherwise known as “stairs”) at edges (e.g., ends) of the tiers of the stack. Conventionally, the steps have treads (e.g., upper surfaces) defined by contact regions of conductive structures of the device, such as of access lines (e.g., word lines), which may be formed by the conductive materials of the tiered stack. Contact structures may be formed in physical contact with the steps to provide electrical access to the conductive structures (e.g., word lines) associated with the steps. The contact structures may be in electrical communication, via conductive routing lines, to additional contact structures that communicate to a source/drain region. String drivers drive the access line (e.g., word line) voltages to write to or read from the memory cells controlled via the access lines (e.g., word lines).

A continued goal in the microelectronic device fabrication industry is to minimize the footprint of the features of microelectronic devices so as to maximize the number of devices, and functional features thereof, in a given structural area. However, accurately and consistently fabricating 3D NAND memory device features—such as steps and the contact structures that extend thereto—continues to present challenges, particularly as devices and their features are scaled to smaller footprint sizes.

### BRIEF DESCRIPTION OF THE DRAWINGS

FIG. 1 is a schematic, cross-sectional, perspective view of a microelectronic device structure of a microelectronic device, according to embodiments of the disclosure.

FIG. 2 is an enlarged view of the area of box 110 of FIG. 1.

FIG. 3A is a top plan, schematic view of the microelectronic device structure of FIG. 1, wherein the front of FIG. 1 corresponds to a view from section line C-C of FIG. 3A.

FIG. 3B is an enlarged view of the area of box 304 of FIG. 3A.

FIG. 4 is an enlarged view of the area of boxes 154 of FIG. 1, illustrating a multi-series stadium including at least one series of to-step contacts and at least one series of through-step contacts, according to embodiments of the disclosure.

FIG. 5 is an enlarged view of the area of boxes 158 of FIG. 1, illustrating a single-series stadium that includes both to-step contacts and through-step contacts, according to embodiments of the disclosure.

FIG. 6 is an enlarged view corresponding to the area of boxes 158 of FIG. 1, illustrating a single-set stadium that includes all to-step contacts, according to embodiments of the disclosure.

FIG. 7 is a schematic, cross-sectional, elevational front elevational view of a microelectronic device structure that includes a series of stadiums that may include the stadiums illustrated in FIG. 1, including at least one multi-series stadium (e.g., of FIG. 4) and at least one single-series stadium (e.g., of FIG. 5 and/or of FIG. 6), in accordance with embodiments of the disclosure.

FIG. 8 through FIG. 28 are schematic, cross-sectional, perspective views of various stages of processing to fabricate the structure of FIG. 27 and/or the structure of FIG. 28, either or both of which structures may be part(s) of a microelectronic device structure in accordance with embodiments of the disclosure, such as any of the aforementioned microelectronic device structures of FIG. 1 and FIG. 3A.

FIG. 27 is a schematic, cross-sectional, perspective view of a structure of a multi-series stadium (e.g., FIG. 4) of a microelectronic device structure (e.g., FIG. 1 and FIG. 3A), according to embodiments of the disclosure and which may be formed according to the fabrication processing stages illustrated in FIG. 8 through FIG. 27, wherein the view of FIG. 27 corresponds to section line A-A of FIG. 1 and FIG. 3A.

FIG. 28 is a schematic, cross-sectional, perspective view of a structure of a single-series stadium (e.g., FIG. 5) of a microelectronic device structure (e.g., FIG. 1 and FIG. 3A), according to embodiments of the disclosure and which may be formed according to the fabrication processing stages illustrated in FIG. 8 through FIG. 26 then FIG. 28, wherein the view of FIG. 28 corresponds to section line B-B of FIG. 1 and FIG. 3A.

FIG. 29 is a block diagram of an electronic system including a microelectronic device that includes at least one microelectronic device structure of embodiments of the disclosure.

### DETAILED DESCRIPTION

Structures (e.g., microelectronic device structures), apparatuses (e.g., microelectronic devices), and systems (e.g., electronic systems), according to embodiments of the disclosure, include a stack of vertically alternating conductive structures and insulative structures arranged in tiers. A series of stadiums is patterned into the tiered stack with non-patterned “crest” portions of the stack spacing neighboring stadiums from one another. The stadiums include staircase structures having steps at ends of some tiers of the stack. The steps include treads defined, at least in part, by upper horizontal surfaces of conductive structures of the tiers that include such exposed surfaces. In at least some of the step treads, a metal oxide region is included and extends through the conductive structure that provides the remaining portion of the step tread. Conductive “line contacts” (e.g., access line contacts, word line contacts) extend to the conductive structures of the staircases. In at least one stadium, the line contacts include both “to-step contacts” and “through-step contacts.” Each “to-step contact” extends to “land on” the conductive structure providing a portion of a tread of a defined step of the staircase. Each “through-step contact” extends through the metal oxide region of at least one tread to land on a lower conductive structure that does not otherwise have an exposed step tread. The metal oxide region may be formed by methods that facilitate accurate and consistent formation of the metal oxide region throughout a stadium area of the device. Also, a stadium accommodating “X” number of line contacts may include relatively fewer (e.g., half as many) steps of relatively greater tread area (e.g., twice the area) compared to, for example, the line contacts in a stadium having treads of a lesser area (e.g., half the area) and provided at each conductive structure of the tiered stack. The greater-area step treads may be relatively easier to fabricate precisely and accurately and may lessen the risk of contact misalignments and electrical shorting between contacts and non-target conductive structures.

As used herein, the term “series” means and refers to a group of items arranged substantially in a row (e.g., in the illustrated X-axis direction).

As used herein, the term “series of stadiums” means and refers to a group of stadiums distributed across a stack structure in a row (e.g., in the illustrated X-axis direction), with neighboring stadiums spaced from one another by a non-patterned “crest” portion of the stack.

As used herein, the term “set of staircases” means and refers to one or more staircases that collectively define a row (e.g., in the illustrated X-axis direction) of steps, each of which steps may be at a respectively different tier elevation of a stack structure. A respective “set of staircases” may include one or more descending staircases, one or more ascending staircases, or any combination thereof.

As used herein, the term “descending staircase” means and refers to a staircase generally exhibiting negative slope, as defined by a phantom line extending from a vertically highest step of the staircase to a vertically lowest step of the staircase.

As used herein, the term “ascending staircase” means and refers to a staircase generally exhibiting positive slope, as defined by a phantom line extending from a vertically highest step of the staircase to a vertically lowest step of the staircase.

As used herein, the term “high-aspect-ratio” means and refers to a height-to-width (e.g., a ratio of a maximum height to a maximum width) of greater than about 10:1 (e.g., greater than about 20:1, greater than 30:1, greater than about 40:1, greater than about 50:1, greater than about 60:1, greater than about 70:1, greater than about 80:1, greater than about 90:1, greater than about 100:1).

As used herein, a feature referred to with the adjective “source/drain” means and refers to the feature being configured for association with either or both the source region and the drain region of the device that includes the “source/drain” feature. A “source region” may be otherwise configured as a “drain region” and vice versa without departing from the scope of the disclosure.

As used herein, the terms “opening,” “trench,” and “slit” mean and include a volume extending through or into at least one structure or at least one material, leaving a gap in that at least one structure or at least one material, or a volume extending between structures or materials, leaving a gap between the structures or materials. Unless otherwise described, an “opening,” “trench,” and/or “slit” is not necessarily empty of material. That is, an “opening,” “trench,” or “slit” is not necessarily void space. An “opening,” “trench,” or “slit” formed in or between structures or materials may comprise structure(s) or material(s) other than that in or between which the opening is formed. And, structure(s) or material(s) “exposed” within an opening, trench, or slit is/are not necessarily in contact with an atmosphere or non-solid environment. Structure(s) or material(s) “exposed” within an opening, trench, or slit may be adjacent or in contact with other structure(s) or material(s) that is/are disposed within the opening, trench, or slit.

As used herein, the terms “substrate” and “base structure” mean and include a base material or other construction upon which components, such as tiered stacks and structures therein, are formed. The substrate or base structure may be a semiconductor substrate, a base semiconductor material on a supporting structure, a metal electrode, or a semiconductor substrate having one or more materials, structures, or regions formed thereon. The substrate may be a conventional silicon substrate or other bulk substrate including a semiconductive material. As used herein, the term “bulk substrate” means and includes not only silicon wafers, but also silicon-on-insulator (“SOT”) substrates, such as silicon-on-sapphire (“SOS”) substrates or silicon-on-glass (“SOG”) substrates, epitaxial layers of silicon on a base semiconductor foundation, or other semiconductor or optoelectronic materials, such as silicon-germanium (Si₁₋ₓGeₓ, where x is, for example, a mole fraction between 0.2 and 0.8), germanium (Ge), gallium arsenide (GaAs), gallium nitride (GaN), or indium phosphide (InP), among others. Furthermore, when reference is made to a “substrate” or “base structure” in the following description, previous process stages may have been utilized to form materials, structures, or junctions in the base semiconductor structure, base structure, or other foundation.

As used herein, the terms “insulative” and “insulating,” when used in reference to a material or structure, means and includes a material or structure that is electrically insulative or electrically insulating. An “insulative” or “insulating” material or structure may be formed of and include one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric carboxynitride material (e.g., a silicon carboxynitride (SiOₓC_{z}N_{y})), and/or air. Formulae including one or more of “x,” “y,” and/or “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and/or “z” atoms of an additional element (if any), respectively, for every one atom of another element (e.g., Si, Al, Hf, Nb, Ti). As the formulae are representative of relative atomic ratios and not strict chemical structure, an insulative material or insulative structure may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative” or “insulating” structure means and includes a structure formed of and including “insulative” or “insulating” material.

As used herein, the term “sacrificial,” when used in reference to a material or structure, means and includes a material or structure that is formed during a fabrication process but which is removed (e.g., substantially removed) prior to completion of the fabrication process.

As used herein, the term “horizontal” means and includes a direction that is parallel to a primary surface of the substrate on which the referenced material or structure is located. The “width” and “length” of a respective material or structure may be defined as dimensions in a horizontal plane. With reference to the figures, the “horizontal” direction may be perpendicular to an indicated “Z” axis, may be parallel to an indicated “X” axis, and may be parallel to an indicated “Y” axis.

As used herein, the term “lateral” means and includes a direction in a horizontal plane parallel to a primary surface of the substrate on which a referenced material or structure is located and substantially perpendicular to a “longitudinal” direction. The “width” of a respective material or structure may be defined as a dimension in the lateral direction of the horizontal plane. With reference to the figures, the “lateral” direction may be parallel to an indicated “X” axis, may be perpendicular to an indicated “Y” axis, and may be perpendicular to an indicated “Z” axis.

As used herein, the term “longitudinal” means and includes a direction in a horizontal plane parallel to a primary surface of the substrate on which a referenced material or structure is located, and substantially perpendicular to a “lateral” direction. The “length” of a respective material or structure may be defined as a dimension in the longitudinal direction of the horizontal plane. With reference to the figures, the “longitudinal” direction may be parallel to an indicated “Y” axis, may be perpendicular to an indicated “X” axis, and may be perpendicular to an indicated “Z” axis.

As used herein, the term “vertical” means and includes a direction that is perpendicular to a primary surface of the substrate on which a referenced material or structure is located. The “height” of a respective material or structure may be defined as a dimension in a vertical plane. With reference to the figures, the “vertical” direction may be parallel to an indicated “Z” axis, may be perpendicular to an indicated “X” axis, and may be perpendicular to an indicated “Y” axis.

As used herein, the term “width” means and includes a dimension, along an indicated “X” axis in a horizontal plane (e.g., at a certain elevation, if identified), defining a maximum distance, along such “X” axis in the horizontal plane, of the whole of the material or structure in question or of a concerned portion of the material or structure in question. For example, a width of a conductive structure may be a maximum X-axis dimension from one lateral end of the conductive structure to an opposite lateral end of the structure, whereas a width of a step defined by the conductive structure may be a maximum X-axis dimension of only that portion of the conductive structure that provides the step.

As used herein, the term “length” means and includes a dimension, along an indicated “Y” axis in a horizontal plane (e.g., at a certain elevation, if identified), defining a maximum distance, along such “Y” axis in the horizontal plane, of the material or structure in question or of a concerned portion of the material or structure in question. For example, a length of a conductive structure may be a maximum Y-axis dimension from one block-defining slit to another block-defining slit, whereas a length of a step defined by the conductive structure may be a maximum Y-axis dimension of only that portion of the conductive structure that provides the step.

As used herein, the terms “thickness” or “thinness” are spatially relative terms that mean and include a dimension in a straight-line direction that is normal to the closest surface of an immediately adjacent material or structure that is of a different composition or that is otherwise distinguishable from the material or structure whose thickness, thinness, or height is discussed.

As used herein, the term “between” is a spatially relative term used to describe the relative disposition of one material or structure relative to at least two other materials or structures. The term “between” may encompass both a disposition of one material or structure directly adjacent the other materials or structures and a disposition of one material or structure indirectly adjacent to the other materials or structures.

As used herein, the term “proximate” is a spatially relative term used to describe disposition of one material or structure near to another material or structure. The term “proximate” includes dispositions of indirectly adjacent to, directly adjacent to, and internal to.

As used herein, features (e.g., regions, materials, openings, structures, assemblies, devices) described as “neighboring” one another mean and include features of the disclosed identity (or identities) that are located most proximate (e.g., closest to) one another. One or more additional features (e.g., additional regions, additional materials, additional structures, additional openings, additional assemblies, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with the “neighboring” features is positioned between the “neighboring” features. For example, a structure of material X “neighboring” a structure of material Y is the first material X structure, e.g., of multiple material X structures, that is nearest the particular structure of material Y. Accordingly, features described as “vertically neighboring” one another mean and include features of the disclosed identity (or identities) that are located most vertically proximate (e.g., vertically closest to) one another. Moreover, features described as “horizontally neighboring” one another mean and include features of the disclosed identity (or identities) that are located most horizontally proximate (e.g., horizontally closest to) one another.

As used herein, the term “consistent”—when referring to a parameter, property, or condition of one structure, material, feature, or portion thereof in comparison to the parameter, property, or condition of another such structure, material, feature, or portion of such same aforementioned structure, material, or feature—is a relative term that means and includes the parameter, property, or condition of the two such structures, materials, features, or portions being equal, substantially equal, or about equal, at least in terms of respective dispositions of such structures, materials, features, or portions. For example, two structures having “consistent” heights as one another may each define a same, substantially same, or about the same height, from a lower surface to an upper surface of each respective such structure, despite the two structures being at different elevations of a larger structure.

As used herein, the terms “about” and “approximately,” when either is used in reference to a numerical value for a particular parameter, are inclusive of the numerical value and a degree of variance from the numerical value that one of ordinary skill in the art would understand is within acceptable tolerances for the particular parameter. For example, “about” or “approximately,” in reference to a numerical value, may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “substantially,” when referring to a parameter, property, or condition, means and includes the parameter, property, or condition being equal to or within a degree of variance from a given value such that one of ordinary skill in the art would understand such given value to be acceptably met, such as within acceptable manufacturing tolerances. By way of example, depending on the particular parameter, property, or condition that is substantially met, the parameter, property, or condition may be “substantially” a given value when the value is at least 90.0 percent met, at least 95.0 percent met, at least 99.0 percent met, or even at least 99.9 percent met.

As used herein, the terms “on” or “over,” when referring to an element as being “on” or “over” another element, are spatially relative terms that mean and include the element being directly on top of, adjacent to (e.g., laterally adjacent to, horizontally adjacent to, longitudinally adjacent to, vertically adjacent to), underneath, or in direct contact with the other element. It also includes the element being indirectly on top of, adjacent to (e.g., laterally adjacent to, horizontally adjacent to, longitudinally adjacent to, vertically adjacent to), underneath, or near the other element, with other elements present therebetween. In contrast, when an element is referred to as being “directly on” or “directly adjacent to” another element, there are no intervening elements present.

As used herein, other spatially relative terms, such as “below,” “lower,” “bottom,” “above,” “upper,” “top,” and the like, may be used for ease of description to describe one element's or feature's relationship to another element(s) or feature(s) as illustrated in the figures. Unless otherwise specified, any spatially relative terms used in this disclosure are intended to encompass different orientations of the materials in addition to the orientation as depicted in the figures. For example, if materials in the figures are inverted, elements described as “below” or “under” or “on bottom of” other elements or features would then be oriented “above” or “on top of” the other elements or features. Thus, the term “below” may encompass both an orientation of above and below, depending on the context in which the term is used, which will be evident to one of ordinary skill in the art. The materials may be otherwise oriented (rotated ninety degrees, inverted, etc.) and the spatially relative descriptors used herein interpreted accordingly.

As used herein, the terms “level” and “elevation” are spatially relative terms used to describe one material's or feature's relationship to another material(s) or feature(s) as illustrated in the figures, using—as a reference point—the lowest illustrated surface of the structure that includes the materials or features. As used herein, a “level” and an “elevation” are each defined by a horizontal plane parallel to a primary surface of the substrate or base structure on or in which the structure (that includes the materials or features) is formed. When used with reference to the drawings, “lower levels” and “lower elevations” are relatively nearer to the bottom-most illustrated surface of the respective structure, while “higher levels” and “higher elevations” are relatively further from the bottom-most illustrated surface of the respective structure.

As used herein, the term “depth” is a spatially relative term used to describe one material's or feature's relationship to another material(s) or feature(s) as illustrated in the figures, using—as a reference point—the highest illustrated surface of the structure (e.g., stack structure) that includes the materials or features. When used with reference to the drawings, a “depth” is defined by a horizontal plane parallel to the highest illustrated surface of the structure (e.g., stack structure) that includes the materials or features.

Unless otherwise specified, any spatially relative terms used in this disclosure are intended to encompass different orientations in addition to the orientation as depicted in the drawings. For example, the materials in the drawings may be inverted, rotated, etc., with the “upper” levels and elevations then illustrated proximate the bottom of the page, the “lower” levels and elevations then illustrated proximate the top of the page, and the greatest “depths” extending a greatest vertical distance upward.

As used herein, the terms “comprising,” “including,” “having,” and grammatical equivalents thereof are inclusive, open-ended terms that do not exclude additional, unrecited elements or method steps. These terms also include more restrictive terms “consisting of” and “consisting essentially of” and grammatical equivalents thereof. Therefore, a structure described as “comprising,” “including,” and/or “having” a material may be a structure that, in some embodiments, includes additional material(s) as well and/or a structure that, in some embodiments, does not include any other material(s). Likewise, a material (e.g., composition) described as “comprising,” “including,” and/or “having” a species may be a material that, in some embodiments, includes additional species as well and/or a material that, in some embodiments, does not include any other species.

As used herein, the term “may” with respect to a material, structure, feature, or method act indicates that such is contemplated for use in implementation of an embodiment of the disclosure and such term is used in preference to the more restrictive term “is” so as to avoid any implication that other, compatible materials, structures, features, and methods usable in combination therewith should or must be excluded.

As used herein, “and/or” means and includes any and all combinations of one or more of the associated listed items.

As used herein, the singular forms “a,” “an,” and “the” are intended to include the plural forms as well, unless the context clearly indicates otherwise.

As used herein, an “(s)” at the end of a term means and includes the singular form of the term and/or the plural form of the term, unless the context clearly indicates otherwise.

As used herein, the terms “configured” and “configuration” mean and refer to a size, shape, material composition, orientation, and arrangement of a referenced feature (e.g., region, material, structure, opening, assembly, device) so as to facilitate a referenced operation or property of the referenced feature in a predetermined way.

The illustrations presented herein are not meant to be actual views of any particular material, structure, sub-structure, region, sub-region, device, system, or stage of fabrication, but are merely idealized representations that are employed to describe embodiments of the disclosure.

Embodiments are described herein with reference to cross-sectional illustrations that are schematic illustrations. Accordingly, variations from the shapes of the illustrations as a result, for example, of manufacturing techniques and/or tolerances, are to be expected. Thus, embodiments described herein are not to be construed as limited to the particular shapes or structures as illustrated but may include deviations in shapes that result, for example, from manufacturing techniques. For example, a structure illustrated or described as box-shaped may have rough and/or nonlinear features. Moreover, sharp angles that are illustrated may be rounded; surfaces and features illustrated to be vertical may be non-vertical, bent, and/or bowed; and/or structures illustrated with consistent transverse widths and/or lengths throughout the height of the structure may taper in transverse width and/or length. Thus, the materials, features, and structures illustrated in the figures are schematic in nature and their shapes are not intended to illustrate the precise shape of a material, feature, or structure and do not limit the scope of the present claims.

The following description provides specific details, such as material types and processing conditions, to provide a thorough description of embodiments of the disclosed apparatus (e.g., devices, systems) and methods. However, a person of ordinary skill in the art will understand that the embodiments of the apparatus and methods may be practiced without employing these specific details. Indeed, the embodiments of the apparatus and methods may be practiced in conjunction with conventional semiconductor fabrication techniques employed in the industry.

The fabrication processes described herein do not form a complete process flow for processing apparatus (e.g., devices, systems) or the structures thereof. The remainder of the process flow is known to those of ordinary skill in the art. Accordingly, only the methods and structures necessary to understand embodiments of the present apparatus (e.g., devices, systems) and methods are described herein.

Unless the context indicates otherwise, the materials described herein may be formed by any suitable technique including, but not limited to, spin coating, blanket coating, chemical vapor deposition (“CVD”), atomic layer deposition (“ALD”), plasma enhanced ALD, physical vapor deposition (“PVD”) (e.g., sputtering), or epitaxial growth. Depending on the specific material to be formed, the technique for depositing or growing the material may be selected by a person of ordinary skill in the art.

Unless the context indicates otherwise, the removal of materials described herein may be accomplished by any suitable technique including, but not limited to, etching (e.g., dry etching, wet etching, vapor etching), ion milling, abrasive planarization, or other known methods.

In referring to the drawings, like numerals refer to like components throughout. The drawings are not necessarily drawn to scale.

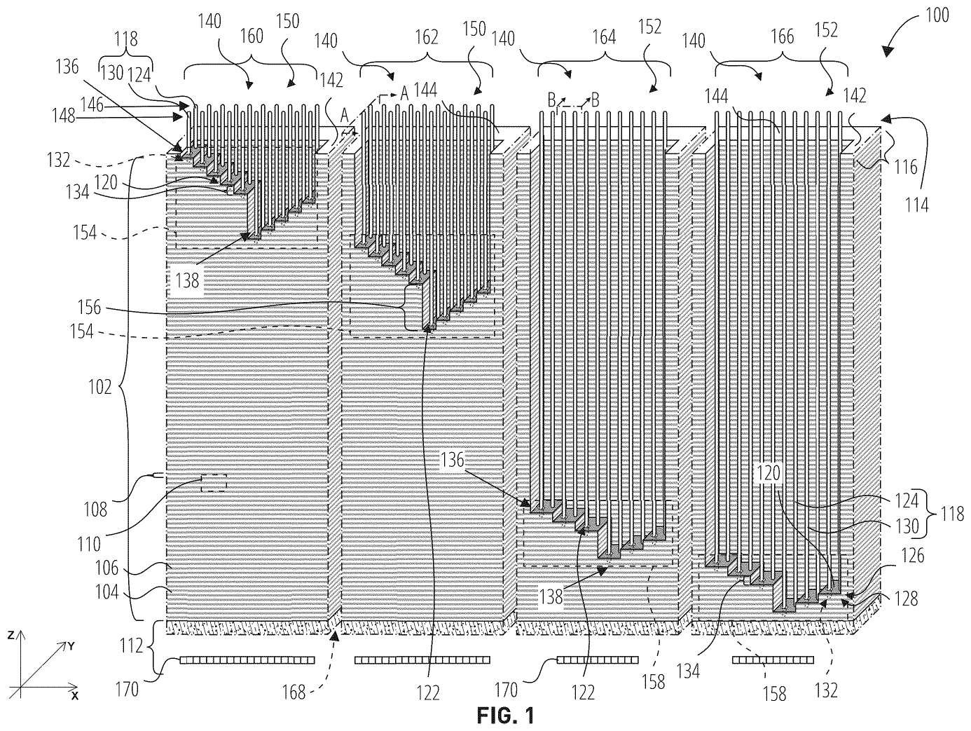

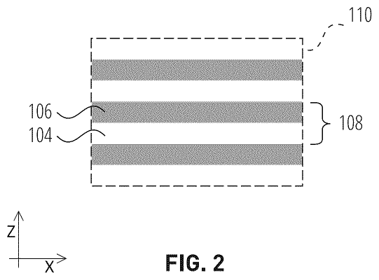

With reference to FIG. 1, illustrated is a microelectronic device structure 100 that includes a stack 102 (which may otherwise be referred to herein as a “stack structure” or as a “tiered stack”) of vertically alternating (e.g., vertically interleaved) insulative structures 104 and conductive structures 106 arranged in tiers 108. Each tier 108—as the term “tier” is used herein—includes one of the insulative structures 104 and one of the conductive structures 106 vertically neighboring the one of the insulative structures 104. This vertically alternating, interleaved arrangement of the insulative structures 104 and the conductive structures 106 providing the tiers 108 is illustrated in greater detail in FIG. 2, which is an enlargement of area box 110 of FIG. 1, but may be equally illustrative of other portions of the stack 102.

With continued reference to FIG. 1, the number (e.g., quantity) of tiers 108 (and conductive structures 106) illustrated is for example only, and the disclosure is not so limiting. For example, a microelectronic device structure, in accordance with embodiments of the disclosure, may include a different quantity of the tiers 108 (e.g., and of the conductive structures 106) in the stack 102. In some embodiments, the stack 102 includes one-hundred twenty-six or one-hundred twenty-eight of the tiers 108 (and of the conductive structures 106). The number (e.g., quantity) of the tiers 108—and therefore of the conductive structures 106—of the stack 102 may be within a range of from thirty-two to three-hundred or more. The tiers 108 may be included in one or more decks of the stack 102.

The conductive structures 106 may be formed of and include (e.g., each be formed of and include) one or more conductive materials, such as one or more of: at least one metal (e.g., one or more of tungsten, titanium, nickel, platinum, rhodium, ruthenium, iridium, aluminum, copper, molybdenum, cobalt, silver, gold), at least one alloy (e.g., an alloy of one or more of the aforementioned metals), and at least one metal-containing material that includes one or more of the aforementioned metals (e.g., metal nitrides, metal silicides, metal carbides, metal oxides, such as a material including one or more of titanium nitride (TiN), tantalum nitride (TaN), tungsten nitride (WN), titanium aluminum nitride (TiAlN), iridium oxide (IrOₓ), ruthenium oxide (RuOₓ), alloys thereof). In some embodiments, the conductive structures 106 include at least one of the aforementioned conductive materials along with at least one additional of the aforementioned conductive materials formed as a liner (e.g., tungsten within a tungsten nitride liner). Some or all of the conductive structures 106 may have the same (e.g., consistent) or different thicknesses (e.g., heights) as one another.

The insulative structures 104 may be formed of and include (e.g., each be formed of and include) at least one insulative material, such as a dielectric oxide material (e.g., silicon dioxide). In this and other embodiments described herein, the insulative material of the insulative structures 104 may be substantially the same as or different than other insulative material(s) of the microelectronic device structure 100. Some or all of the insulative structures 104 may have the same (e.g., consistent) or different thicknesses (e.g., heights) as one another. In some embodiments, some of the insulative structures 104 (e.g., an uppermost, a lowest, and/or intermediate insulative structures 104) are relatively thicker than others of the insulative structures 104 in the stack 102.

The stack 102 may be provided on or over a base structure 112, which may include one or more regions formed of and including, for example, one or more semiconductor materials (e.g., polycrystalline silicon (polysilicon)) doped with one or more P-type conductivity chemical species (e.g., one or more of boron, aluminum, and gallium) and/or one or more N-type conductivity chemical species (e.g., one or more of arsenic, phosphorous, and antimony) to provide one or more source/drain regions of the microelectronic device structure 100.

In addition to the semiconductor materials and/or source/drain region, the base structure 112 may include other base material(s) or structure(s), such as conductive regions for making electrical connections with other conductive structures of the device that includes the microelectronic device structure 100. In some such embodiments, CMOS (complementary metal-oxide-semiconductor) circuitry is included, within the base structure 112, in a CMOS region below the source/drain region, which CMOS region may be characterized as a so-called “CMOS under Array” (“CuA”) region.

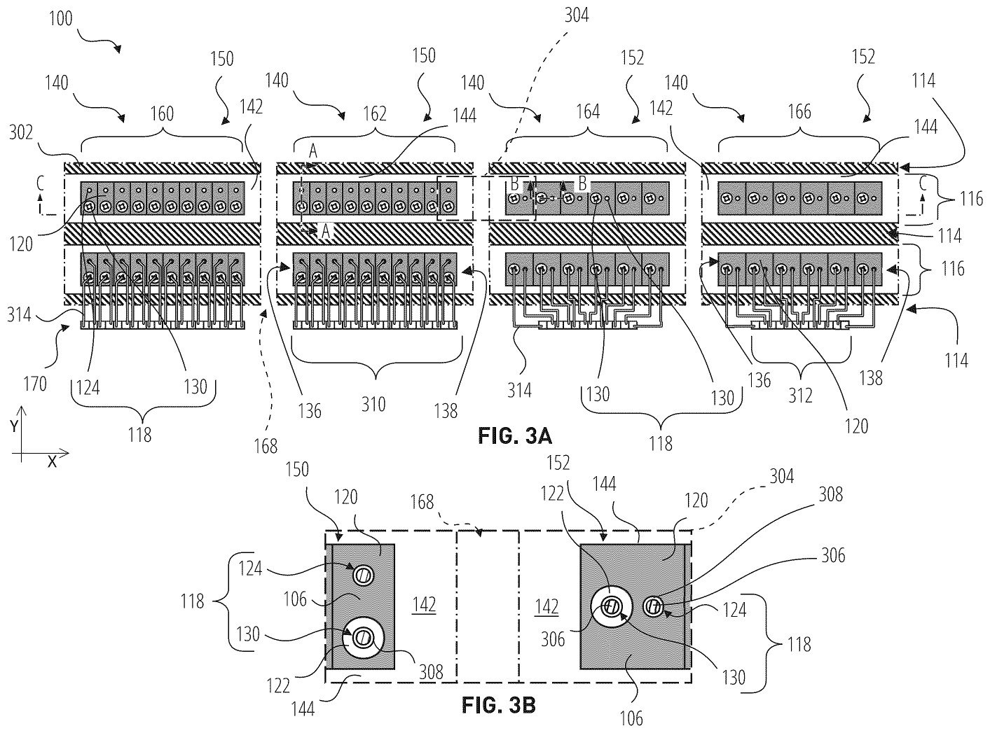

With continued reference to FIG. 1 and also with reference to FIG. 3A—which is a top plan view of the microelectronic device structure 100 of FIG. 1—a series of slits 114 or other elongate structures may extend through the stack 102 (e.g., to and/or into the base structure 112) to divide the stack 102 into a series of blocks 116 that extend in the lateral direction (e.g., with a greater dimension (e.g., width) in the “X”-axis direction than a dimension (e.g., length) in the “Y”-axis direction).

FIG. 3A is a top plan view of a pair of neighboring blocks 116 including the block 116 illustrated in FIG. 1. As illustrated in FIG. 3A, a pair of slits 114 may be formed, parallel to the “X”-axis, to define the front and rear of a respective one of the blocks 116 of the microelectronic device structure 100. A longitudinally forward and/or rearward neighboring block 116, to the block 116 of FIG. 1, may be similarly structured to the block 116 of FIG. 1 such that the illustration of FIG. 1 may represent such neighboring blocks 116 as well. Alternatively, such neighboring blocks 116 may have structures substantially mirrored to that of the block 116 of FIG. 1, reflected about the slit 114 that separates the blocks 116 from one another. The slits 114 may be substantially filled with non-conductive material(s) 302 (e.g., with a liner, without a liner) to form one slit structure between each pair of neighboring blocks 116.

Other portions of the microelectronic device structure 100 (e.g., portions horizontally disposed relative to the portions illustrated in, e.g., FIG. 1 and FIG. 3A) may include array(s) of pillars (e.g., including channel material and memory material) extending through the stack 102 and to and/or into the base structure 112 (e.g., to and/or into a source/drain region). The pillars may effectuate the formation of strings of memory cells of a memory device (e.g., a memory device including any of the microelectronic device structures described or illustrated herein). The conductive structures 106 of the tiers 108 may be coupled to, or may form control gates of, the memory cells effectuated by the pillars. For example, each conductive structure 106 may be coupled to an individual memory cell of a particular string (e.g., effectuated by a particular pillar) of memory cells.

With returned reference to FIG. 1, to facilitate electrical communication to particular selected conductive structures 106 within the stack 102, conductive contact structures—referred to herein as “line contacts” 118 extend to (or from) and physically contact the conductive structures 106 of the tiers 108. Each such line contact 118 is positioned to physically contact a particular one of the conductive structures 106.

Some of the line contacts 118 are positioned and formed to physically contact (e.g., “land on”) a particular one of the conductive structures 106 at an exposed upper (e.g., horizontal) surface portion of that conductive structure 106. Each of these areas of exposed upper surface portions is referred to herein as a “tread” of a “step” 120. At the distal end of the step 120 tread, a combination of substantially co-planar, vertical sidewall(s) of stack 102 structures (e.g., conductive structures 106 and insulative structures 104) provide a “riser” of the step 120.

To provide the steps 120 of the conductive structures 106, the stack 102 is patterned (e.g., etched) to expose the treads of the steps 120, that is, to expose the one or more upper (e.g., horizontal) surface area portions of individual conductive structures 106. More particularly, the tiers 108 are selectively patterned to remove portions of otherwise-overlying tiers 108 to leave exposed (until otherwise covered by fill material(s) and/or line contacts 118) at least one upper surface area of the conductive structure 106 of the next lower tier 108.

Some or all step 120 treads also include at least one metal oxide region 122 that extends through the conductive structure 106 of the step 120. Accordingly, for at least some steps 120, each exposed area of conductive structure 106 and metal oxide region 122 provides one tread of the steps 120. In some embodiments, one or more other steps 120 have treads provided wholly by exposed areas of conductive structures 106, without such steps 120 including metal oxide regions 122, as further described below.

With continued reference to FIG. 1, the steps 120 are formed at various elevations (also referred to herein as different “tier elevations”) in the stack 102 so as to provide steps 120 at unique individual conductive structures 106 of the stack 102. The line contacts 118 extend downward, through areas of the stack 102, toward the steps 120 at the various elevations. The microelectronic device structure 100 may include, in each respective block 116, at least one line contact 118 per conductive structure 106 (e.g., per tier 108) in the stack 102.

The line contacts 118 physically contact targeted conductive structures 106 so as to provide electrical and operative connection with the various conductive structures 106 (e.g., word lines) of the stack 102. Some line contacts 118 extend to physically contact (e.g., “land on”) respective conductive structures 106 that provide the steps 120. Other line contacts 118 extend to and through the conductive structures 106 at the steps 120, further extending to and landing on a conductive structure 106 of a tier 108 below the step 120 (e.g., below the metal oxide region 122 of the step 120).

The line contacts 118 that extend to, and physically contact, the conductive structures 106 providing the step 120 treads are referred to herein as “to-step contacts” 124. A lowest surface of a to-step contact 124 may be on or in a conductive structure 106 that provides a step 120 tread, which conductive structure 106 may be referred to herein as being a “treaded” conductive structure 106 and/or in a “treaded” tier 126. The step 120 tread of the treaded tier 126 functions as a landing area for physical contact with at least one of the line contacts 118 configured as a to-step contact 124.

In contrast to the to-step contacts 124, others of the line contacts 118 are positioned and formed to physically contact (e.g., land on) a particular one of the conductive structures 106 at an otherwise covered (e.g., not exposed) upper (e.g., horizontal) surface portion of a targeted conductive structure 106. Such non-step conductive structures 106 may be referred to herein as a “covered” conductive structures 106 and/or as being in a “covered” tier 128.

To reach such covered surface portions of the covered tiers 128, some of the line contacts 118 extend through conductive structures 106 providing step 120 treads (e.g., treaded conductive structures 106) and continue to extend to targeted conductive structures 106 that are vertically below the conductive structures 106 of the step 120. The line contacts 118 of this type are referred to herein as “through-step contacts” 130. A through-step contact 130 has a lowest surface that is on or in a conductive structure 106 that does not provide a step 120 tread. Compared to a to-step contact 124 landing on a particular step 120 tread, a through-step contact 130 extending through that step 120 tread includes an extension 132 of at least the height of one tier 108.

The through-step contacts 130 extend through the conductive structures 106 of the step 120 treads within the horizontal area of metal oxide regions 122, which metal oxide regions 122 are illustrated in enlarged view in FIG. 3B (corresponding to box 304 of FIG. 3A). The area of the upper surface of the covered conductive structure 106 (of the covered tier 128) that is vertically below the metal oxide region 122 of a step 120 of a treaded tier 126 is the conductive structure 106 that functions as a landing area for physical contact with at least one of the through-step contacts 130.

The metal oxide regions 122 may be formed of and include substantially the same metal(s) as included in the conductive structures 106 that otherwise provide the steps 120, and may further include oxygen (O) such that the metal oxide regions 122 are formed of and include metal oxide material(s) that are non-conductive (e.g., insulative). For example, in embodiments in which the conductive structures 106 are formed of and include tungsten (W), the metal oxide regions 122 may be formed of and include tungsten oxide (e.g., WO₃); in embodiments in which the conductive structures 106 are formed of titanium (Ti), the metal oxide regions 122 may be formed of and include titanium oxide (e.g., TiO₂); in embodiments in which the conductive structures 106 are formed of and include cobalt (Co), the metal oxide regions 122 may be formed of and include cobalt oxide (e.g., CoO); and in embodiments in which the conductive structures 106 are formed of and include molybdenum (Mo), the metal oxide regions 122 may be formed of and include molybdenum oxide (e.g., MoO₂, MoO₃). In embodiments in which the conductive structures 106 are formed of and include multiple metals in distinguishable regions, such as in a metal nitride (e.g., tungsten nitride, titanium nitride) liner region and in a metal core (e.g., tungsten, titanium) region, the metal oxide regions 122 may be formed of and include a metal oxynitride liner (e.g., tungsten oxynitride, titanium oxynitride) region and a metal oxide (e.g., tungsten oxide, titanium oxide) core region. In embodiments in which the conductive structures 106 are formed of and include conductive metal oxide material(s) (e.g., iridium oxide (IrOₓ), ruthenium oxide (RuOₓ)), the metal oxide regions 122 may include the metal oxide material(s) with a greater oxygen-to-metal ratio compared to the metal oxide of the conductive structures 106 so that the metal oxide material(s) of the metal oxide regions 122 are non-conductive (e.g., insulative). The amount of oxygen (O) in the metal oxide material(s) of the metal oxide regions 122 may be tailored to achieve the desired level of electrical insulation, e.g., with a minimum oxygen concentration in the metal oxide material(s) of at least 5 at. % (e.g., within a range from about 5 at. % to about 72 at. %).

The non-conductive metal oxide material(s) of the metal oxide regions 122 may electrically isolate and physically space the through-step contacts 130 from the conductive structures 106 of the steps 120. More particularly, the metal oxide regions 122 may electrically isolate and physically space the conductive structures 106 of the steps 120 from conductive material(s) 306 of the through-step contacts 130.

The line contacts 118 (e.g., the to-step contacts 124 and the through-step contacts 130), may be formed of and include conductive material(s) 306 (FIG. 3B) and may, optionally, include one or more insulative contact liners 308 horizontally around the conductive material(s) 306. The conductive material(s) 306 may be formed of and include any conductive material(s) suitable for providing electrically communication between the contacted conductive structures 106 and other electrical components of the microelectronic device. In some embodiments, the conductive material(s) 306 are formed of and include one or more of the conductive material(s) described above with regard to the conductive structures 106. The contact liners 308, if included, may be formed of and include any of the insulative material(s) described above.

In embodiments in which the line contacts 118 (e.g., the to-step contacts 124 and/or the through-step contacts 130) further include the contact liners 308, the contact liners 308 may also contribute to the electrical isolation between the conductive structures 106 of the steps 120 and the conductive material(s) 306 of the through-step contacts 130.

With returned reference to FIG. 1, the through-step contacts 130, which extend through the steps 120 in the area of the metal oxide regions 122, may have a lowest surface that is on or in the conductive structure 106 of a covered tier 128, i.e., on or in a conductive structure 106 that does not provide a step 120 tread. The area—of the covered conductive structure 106 (of the covered tier 128)—that is vertically below the metal oxide region 122 of a step 120 of a treaded tier 126 functions as a landing area for physical contact with at least one of the through-step contacts 130.

With returned reference to FIG. 3B, the metal oxide regions 122 of the steps 120 may be dimensioned so that a diameter of the through-step contacts 130 (whether with or without the contact liners 308) at the elevation of the steps 120 may be less than a diameter of the metal oxide region 122 at the elevation of the steps 120, as illustrated in FIG. 3B. The through-step contacts 130 may be generally centrally disposed within the horizontal area of the metal oxide regions 122, as described further below.

While FIG. 3B illustrates the metal oxide regions 122 as having a generally circular periphery, the disclosure is not so limited. In other embodiments, the metal oxide regions 122 are other than substantially circular in horizontal cross section, such as being substantially rectangular in horizontal cross section, or irregularly shaped in horizontal cross section.

With returned reference to FIG. 1, the steps 120 may be provided by patterning the stack 102 to expose the treads of the steps 120, that is, to expose the one or more upper (e.g., horizontal) surface area portions of individual conductive structures 106. More particularly, the tiers 108 may be selectively patterned to remove portions of otherwise-overlying tiers 108 to leave exposed (until otherwise covered by fill material(s) and/or line contacts 118) at least one upper surface area of the conductive structure 106 of the next lower tier 108. Due to subsequent processing, as described further below, at least some of the step 120 treads provided by the exposed areas also include at least one of the metal oxide regions 122. Accordingly, for at least some steps 120, each exposed area of conductive structure 106 and metal oxide region 122 provides one tread of one of the treaded tiers 126. In some embodiments, some other steps 120 have treads provided wholly by exposed areas of conductive structures 106, without such steps 120 including metal oxide regions 122.

With returned reference to FIG. 1, because individual conductive structures 106 in the stack 102 occupy different elevations of the stack 102 (also referred to herein as different “tier elevations”), the steps 120 are formed at the various elevations of the conductive structures 106. The line contacts 118 of the to-step contact 124 type extend downward to physically contact (e.g., “land on”) respective steps 120, and the line contacts 118 of the through-step contact 130 type extend downward, through the metal oxide regions 122 of respective ones of the steps 120, to land on a respective covered tier 128 below the step 120 (e.g., below the metal oxide region 122 of the step 120).

The height of an individual line contact 118 may be tailored according to the depth (e.g., elevation) of its respective treaded tier 126 or covered tier 128, depending on whether the line contact 118 is a to-step contact 124 or a through-step contact 130, respectively. The line contacts 118 extending to or through steps 120 in relatively higher elevations of the stack 102 may be line contacts 118 that are generally shorter than the line contacts 118 that extend to or through steps 120 in relatively lower elevations of the stack 102. And, each through-step contact 130 that extends through a respective step 120 tread may be taller (e.g., define a vertical, Z-axis dimension that is greater)—than each to-step contact 124 that extends to such respective step 120 tread—by at least the extension 132 height (e.g., at least the height of one tier 108).

The steps 120 may be grouped in “staircases” with each staircase providing at least a part of a row (extending in the X-axis direction) of the steps 120, all or at least some of which are at different tier elevations than others of the steps 120 in the staircase. The tier elevations of the steps 120 of a respective staircase may incrementally decrease or incrementally increase through the staircase according to the height of the step 120 riser, with both the “riser” and the “riser height” indicated in the drawings at reference number 134. For example, in one staircase, the steps 120 may be formed at successively increasing tier 108 (and conductive structure 106) depths (e.g., decreasing tier 108 elevations) to define a descending staircase 136 having generally negative slope. In another staircase, the steps 120 may be formed at successively decreasing tier 108 (and conductive structure 106) depths (e.g., increasing tier 108 elevations) to define an ascending staircase 138 having generally positive slope. The elevation difference between neighboring steps 120 of the row of steps 120 of a respective staircases (e.g., one of the descending staircases 136, one of the ascending staircases 138) defines the riser height 134.

The staircases (e.g., the descending staircases 136 and the ascending staircases 138) may be grouped in so-called “stadiums” 140. One set of staircases extends the width of each stadium 140. As used herein, a “set” of staircases comprises the one or more staircases that are horizontally aligned in the x-axis direction within a respective stadium 140 and that extend the width of the stadium 140. One “set” of staircases may consist of a single (e.g., only one) descending staircase 136 and a single (e.g., only one) ascending staircase 138, such as in the microelectronic device structure 100 illustrated in FIG. 1. In some embodiments, the descending staircase 136 descends toward the ascending staircase 138, as illustrated in FIG. 1. In other embodiments, the ascending staircase 138 ascends toward the descending staircase 136 (such as if the illustrated lateral halves of the stadiums 140 of FIG. 1 were horizontally reversed with one another). In other embodiments, one set of staircases consists of a single descending staircase 136 or a single ascending staircase 138 that extends the whole width of the stadium 140. In other embodiments, more than one descending staircase 136 is included in the set, alone or with one or more ascending staircases 138; or more than one ascending staircase 138 may be included in the set, alone or with one or more descending staircases 136.

The stadiums 140, of a respective block 116 of the microelectronic device structure 100, may be arranged in a series such that multiple stadiums 140 are distributed across a width of the block 116 and extend, in a row (e.g., in the X-axis direction), substantially parallel to the slits 114, as illustrated in FIG. 1 and FIG. 3A. The microelectronic device structure 100 may include as many stadiums 140 at various elevation groups, within a respective block 116 (and stadium series), as necessary for each conductive structure 106 to be connected with at least one to-step contact 124 or at least one through-step contact 130.

Neighboring stadiums 140 may be spaced from one another, in the stadium series of the block 116, by a so-called “crest” 142 of the stack 102. The crests 142 may be formed by areas of the stack 102 where the tiers 108 have not been patterned. The crests 142 may, therefore, extend an entire height of the stack 102. In some embodiments, uppermost boundaries of the crests 142 may be positioned at (e.g., coplanar with) uppermost boundaries of the stack 102. In some embodiments, through-stack conductive structures may be included in the crests 142 and may be in electrical communication between the line contacts 118 (e.g., the to-step contacts 124, the through-step contacts 130) and other electrical components in the base structure 112.

One or more other non-patterned portions of the stack 102 may form one or more so-called “bridges” 144 that extend a width of the block 116. The bridge(s) 144 may extend the entire height of the stack 102. In some embodiments, uppermost boundaries of the bridge(s) 144 are positioned at (e.g., coplanar with) uppermost boundaries of the stack 102. One of the bridges 144 may border one of the slits 114 that define the block 116 length (Y-axis dimension). In some embodiments, each block 116 includes two bridges 144, and each bridge 144 borders a different one of the slits 114 that define the block 116, as illustrated in FIG. 3A. Via the one or more bridges 144, distal portions of a given conductive structure 106 of a respective tier 108 are part of a continuous, single conductive structure 106 of that tier 108. Therefore, an electrical connection between one or more of the line contacts 118 and one of the conductive structures 106 may provide an electrical connection between the one or more line contacts 118 and the whole of the conductive structure 106 throughout the block 116.

Still referring to FIG. 1, one or more insulative fill material(s) (e.g., dielectric material(s)) may substantially fill remaining openings (e.g., trenches)—referred to herein as “stadium openings” (e.g., “stadium trenches”)—vertically overlying and partially defined by the stadiums 140 to electrically insulate the line contacts 118 from one another. The line contacts 118 vertically extend through the insulative fill material(s) to one of the steps 120 treads (for the to-step contacts 124) or through one of the steps 120 treads (e.g., in the metal oxide region 122) to one of the covered tiers 128 (for the through-step contacts 130). For ease of illustration, FIG. 1, FIG. 3A, and FIG. 3B do not illustrate the insulative fill material(s). In some embodiments, the insulative fill material(s) may be one or more dielectric material(s) formed of and including any one or more insulative materials described above.

At least one of the stadiums 140 of the series in the block 116 includes step 120 treads provided by both conductive structures 106 and metal oxide regions 122 formed in those conductive structures 106, and both to-step contacts 124 and through-step contacts 130 are formed within the stadium 140 area. In such stadium 140 areas, the to-step contacts 124 and the through-step contacts 130 may be arranged in multiple series (e.g., multiple parallel rows of the line contacts 118) or in a single series (e.g., a single row of line contacts 118). Stadiums 140 associated with line contacts 118 arranged in multiple rows (e.g., a first series 146 and a second series 148) are referred to herein as “multi-series stadiums” 150. Stadiums 140 associated with line contacts 118 arranged in a single row are referred to herein as “single-series stadiums” 152.

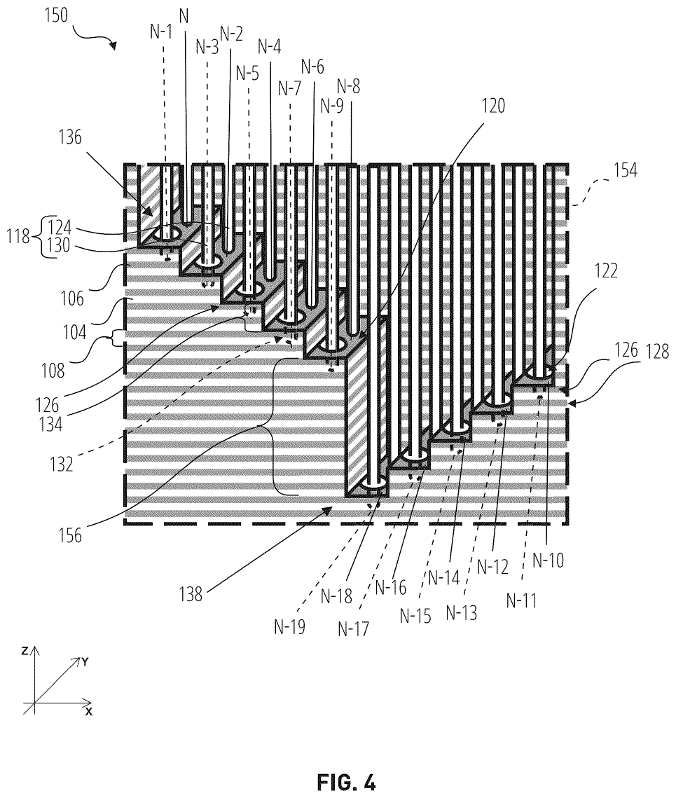

FIG. 4 is an enlarged view, corresponding to boxes 154 of FIG. 1, showing the staircase profile of, and the associated line contacts 118 of, one of the multi-series stadiums 150 of the microelectronic device structure 100 of FIG. 1. This staircase profile and line contacts 118 configuration may be implemented for at least one (e.g., some, half, all) of the stadiums 140 of the series of stadiums 140 of the block 116 (FIG. 1).

In some embodiments, the multi-series stadium 150 includes a single descending staircase 136 and a single ascending staircase 138 (collectively a single “set” of staircases) that together provide a series of steps 120 with each step 120 occupying a unique tier 108 elevation. The staircases may be formed so that—in the tier 108 elevations in which the staircases are defined— about half of the tiers 108 are treaded tiers 126 (e.g., each with a conductive structure 106 providing a step 120 tread in whole or in part) and the other about half of the tiers 108 are covered tiers 128 (e.g., each with a conductive structure 106 that does not provide a step 120 tread). To accomplish this, each of the steps 120 may define a riser height 134, within its respective staircase (e.g., the descending staircase 136, the ascending staircase 138), of a multiple number of the tiers 108 of the stack 102, and one of the staircases (e.g., the descending staircase 136, the ascending staircase 138) may be vertically offset from the other by a vertical distance (e.g., a half-stadium offset 156) at least equaling the number of tiers 108 included in the lower of the staircases (e.g., the lower of the descending staircase 136 and the ascending staircase 138). For example, the riser height 134 may be selected to be a height of two tiers 108, and the half-stadium offset 156 may be selected to be at least ten tiers 108 if the number of steps 120 in the lower staircase (e.g., the ascending staircase 138) is five. Accordingly, the descending staircase 136 may provide step 120 treads at elevations N, N−2, N−4, N−6, and N−8, as illustrated in FIG. 4, and the corresponding ascending staircase 138 of the set may provide steps 120 treads at elevations N−18, N−16, N−14, N−12, and N−10. The elevation of the lowest step 120 of the descending staircase 136 (e.g., elevation N−8) may be at least the riser height 134 (e.g., two tiers 108) above the elevation of the highest step 120 of the ascending staircase 138 (e.g., elevation N−10) so that these steps 120 are at unique tier 108 elevations.

Though FIG. 4 and other figures illustrate the ascending staircase 138—of the multi-series stadium 150—being the half-stadium offset 156 lower than the descending staircase 136, the disclosure is not so limited. In other embodiments, for example, the descending staircase 136 is the half-stadium offset 156 lower than the ascending staircase 138.

With a riser height 134 of, e.g., two tiers 108, the to-step contacts 124 may land on or in the conductive structures 106 of the treaded tiers 126 at the “even elevations” (e.g., N, N−2, N−4, N−6, and N−8 (of the descending staircase 136) and N−18, N−16, N−14, N−12, and N−10 (of the ascending staircase 138)). Correspondingly, the through-step contacts 130, with their at least one-tier extension 132 (e.g., one-tier extension 132) may be extend through the conductive structure 106 (e.g., in the area of the metal oxide region 122, as illustrated in the left-hand side of FIG. 3B) and insulative structure 104 of a respective one of the treaded tiers 126 to land on or in the conductive structure 106 of a respective one of the covered tiers 128, such as a next lower tier 108 to the treaded tier 126 through which the through-step contact 130 extends. Accordingly, the through-step contacts 130 may extend to the covered tiers 128 at the “odd elevations” (e.g., N−1, N−3, N−5, N−7, and N−9 (of the descending staircase 136) and N−19, N−17, N−15, N−13, and N−11 (of the ascending staircase 138)).

Though FIG. 4 and FIG. 1 illustrate the to-step contacts 124 as being in the first series 146 (FIG. 1) to the more rearward side of the through-step contacts 130 of the second series 148 (FIG. 1), the disclosure is not so limited. In other embodiments, the through-step contacts 130 may be in the more rearward first series 146, and the to-step contacts 124 may be in the more forward second series 148. In still other embodiments, the first series 146 may include the to-step contact 124 for some of the steps 120 and the through-step contact 130 for some other of the steps 120, and the second series 148 may include the neighboring through-step contact 130 for the some of the steps 120 and the to-step contact 124 for the some other of the steps 120.

By including both to-step contacts 124 and through-step contacts 130 in the multi-series stadiums 150, the stadium 140 may accommodate “X” number of line contacts 118 without having to pattern “X” number of steps 120. That is, compared to a stadium patterned to define one step per line contact, the multi-series stadium 150 may be fabricated to define significantly fewer (e.g., half as many) steps 120 while still accommodating the same number of line contacts 118. The steps 120, themselves, may therefore be relatively larger in horizontal area (e.g., relatively longer in the Y-axis direction), and a relatively larger step 120 area may be less challenging to fabricate accurately and precisely. For example, the steps 120 may each span the length (e.g., Y-axis direction) between the bridges 144 of the block 116 (FIG. 3A), and each step 120 may be associated with multiple line contacts 118: at least one (e.g., a single one) to-step contact 124 that extends to and physically contacts such step 120 and at least one (e.g., a single one) through-step contact 130 that extends through such step 120 (e.g., in the metal oxide region 122) and physically contacts a next-lower conductive structure 106 of a covered tier 128.

Though FIG. 4 illustrates one to-step contact 124 and one through-step contact 130 associated with each step 120 and a riser height 134 of two tiers 108, the disclosure is not so limited. The riser height 134 and the number of through-step contacts 130 associated with a single step 120 may be otherwise configured. For example, the riser height 134 may be selected to be three tiers 108 (and the half-stadium offset 156 may be selected to be three tiers 108 times (x) the number of steps 120 per the lower of the descending staircase 136 and the ascending staircase 138), and each step 120 may be associated with one to-step contact 124 and two through-step contacts 130. One of the through-step contacts 130 may extend through the step 120 (e.g., in the metal oxide region 122) and terminate at the conductive structure 106 of the vertically neighboring covered tier 128. The other of the through-step contacts 130 may extend through both the step 120 (e.g., in the metal oxide region 122) and the vertically adjacent covered tier 128 (e.g., in a further metal oxide region 122) and terminate at a second vertically adjacent covered tier 128 (e.g., the next-lowest tier 108 of the stack 102). In embodiments with multiple through-step contacts 130 for a single step 120, the metal oxide region 122 of the step 120 may be dimensioned (e.g., with a broad enough area) to accommodate extension through the step 120 tread of all of the through-step contacts 130. In other embodiments with multiple through-step contacts 130 for a single step 120, multiple metal oxide regions 122 may be included in the step 120, such as one for each of the through-step contacts 130.

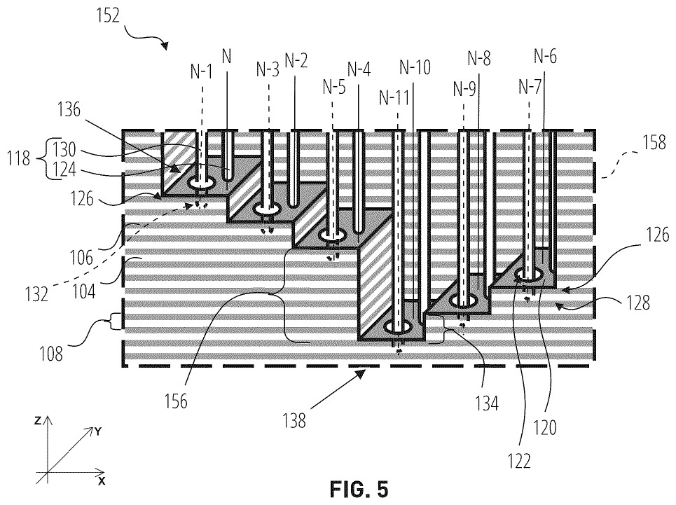

FIG. 5 is an enlarged view, corresponding to boxes 158 of FIG. 1, showing the staircase profile of, and the associated line contacts 118 of, one of the single-series stadiums 152 of the microelectronic device structure 100 of FIG. 1. This staircase profile and line contacts 118 configuration may be implemented for at least one (e.g., some, half, all) of the stadiums 140 of the series of stadiums 140 of the block 116 (FIG. 1).

The single-series stadium 152 may include a single descending staircase 136 and a single ascending staircase 138 (collectively a single “set” of staircases) that together provide a series of steps 120 with each step 120 occupying a unique tier 108 elevation. The staircases (e.g., the descending staircase 136 and the ascending staircase 138) may be designed and formed substantially similarly to those of the multi-series stadium 150, such as with the steps 120 defined at—and to-step contacts 124 extending to—“even elevations” (e.g., elevations N, N−2, and N−4 (in the descending staircase 136) and N−10, N−8, and N−6 (in the ascending staircase 138)), and such as with covered tiers 128 at—and through-step contacts 130 extending to—“odd elevations” (e.g., N−1, N−3, and N−5 (in the descending staircase 136) and N−11, N−9, and N−7 (in the ascending staircase 138)) within the area of metal oxide regions 122. However, some or all of the steps 120 of the single-series stadium 152 may be configured to accommodate laterally adjacent line contacts 118 per step 120.

The line contacts 118 to the single-series stadium 152 may be substantially aligned in a single series (e.g., a single row) in the X-axis direction, as most clearly illustrated in FIG. 3A. However, in other embodiments, one or more of the line contacts 118 may be longitudinally shifted either rearwards or forwards (e.g., closer to one of the bridges 144 (FIG. 3A)) while still providing a single series of line contacts 118.

With a single series of line contacts 118, the single-series stadium 152 may be configured to accommodate relatively fewer line contacts 118 than accommodated in the single-series stadium 152. Therefore, fewer steps 120 may be included in the single-series stadium 152 than in the multi-series stadium 150, and each step 120 of the single-series stadium 152 may be configured to be relatively larger in area than the steps 120 of the single-series stadium 152. For example, each step 120 in the single-series stadium 152 may be substantially the same length (e.g., Y-axis direction) as the steps 120 in the multi-series stadium 150, such as the length between bridges 144 (FIG. 3A), but the steps 120 may be wider (e.g., X-axis direction) than the steps 120 in the multi-series stadium 150. Each step 120 of the single-series stadium 152 may be associated with at least one to-step contact 124 that extends to and physically contacts one of the conductive structures 106 providing a portion of the step 120. Each step 120 of the single-series stadium 152 may also be associated with at least one through-step contact 130 that extends through the step 120 tread in the area of the metal oxide region 122 (see right-hand side of illustration of FIG. 3B) and physically contacts a next-lowest conductive structure 106 of a covered tier 128.

Because the steps 120 of the single-series stadium 152 may be relatively of greater horizontal area than the steps 120 of the multi-series stadium 150, the steps 120 and staircases (e.g., the descending staircase 136, the ascending staircase 138) of the single-series stadium 152 may be relatively less challenging to fabricate with accuracy and precision. Accordingly, the single-series stadiums 152 may be conducive for those stadiums 140 (FIG. 1) that are to be formed at the lowest tiers 108 of the stack 102, where stadium openings in which fabrication acts are performed are at the relatively highest aspect ratios (e.g., relatively greatest height-to-width ratio of the openings).

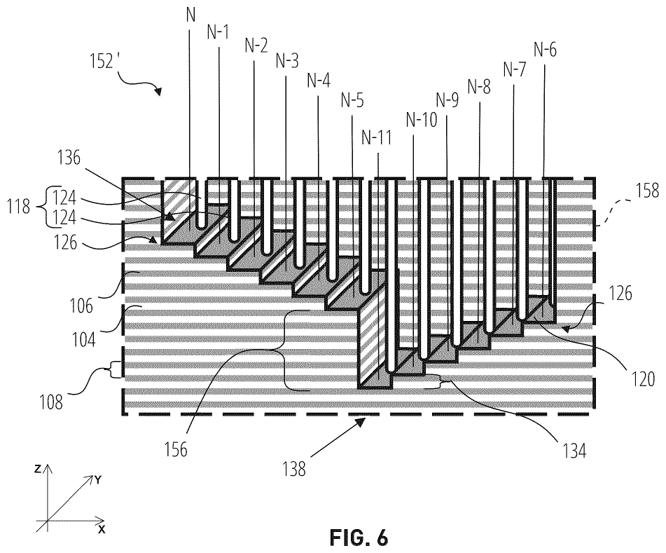

FIG. 6 is an enlarged view, corresponding to boxes 158 of FIG. 1, showing a staircase profile of, and associated line contacts 118 of, a single-series stadium 152′ that may be included in the microelectronic device structure 100 of FIG. 1, such as an alternative to, or in addition to, the single-series stadium 152 of FIG. 5. The staircase(s) (e.g., the descending staircase 136 and the ascending staircase 138) of the single-series stadium 152′ of FIG. 6 may be configured to accommodate a single to-step contact 124 per step 120, without any through-step contacts 130 and without any metal oxide regions 122 (FIG. 3B). To accomplish this, each tier 108 included in the single-series stadium 152′ may be a treaded tier 126, the riser height 134 within each staircase (e.g., the descending staircase 136 and the ascending staircase 138) may be one tier 108, and the half-stadium offset 156 may be at least the number of tiers 108 included in the lower of the staircases (e.g., the ascending staircase 138). The treads of the steps 120 may be defined at—and the to-step contacts 124 may extend to and physically land on—elevations N, N−1, N−2, N−3, N−4, and N−5 (in the descending staircase 136) and N−11, N−10, N−9, N−8, N−7, and N−6 (in the ascending staircase 138). Each step 120 tread may be wholly defined by a respective one of the conductive structures 106.

Accordingly, while at least some stadiums 140 (FIG. 1) of the block 116 may include steps 120 having metal oxide regions 122 through which through-step contacts 130 extend (e.g., such that the at least some stadiums 140 are configured as the multi-series stadium 150 of FIG. 4 and/or the single-series stadium 152 of FIG. 5), one or more other stadiums 140 of the block 116 may have steps 120 without metal oxide regions 122 and these stadiums 140 may be configured for only to-step contacts 124 (e.g., configured as the single-series stadium 152′ of FIG. 6).

Though FIG. 4 illustrates five steps 120 per staircase, FIG. 5 illustrates three steps 120 per staircase, and FIG. 6 illustrates six steps 120 per staircase, the disclosure is not so limited. Any other number (e.g., quantity) of steps 120 may be included in any individual staircase. For example, an individual staircase may include six, seven, eight, or more than eight of the steps 120. Any or all stadiums 140, some or all of the steps 120 of any single staircase (e.g., the descending staircase 136, the ascending staircase 138) and/or of the staircases of any single set of staircases may be configured for both to-step contacts 124 and for through-step contacts 130 by including at least one metal oxide region 122 in the tread of the step 120. One or more other steps 120 of any single staircase and/or set of staircases may be configured for only to-step contacts 124, e.g., by not including the metal oxide region 122 in the tread of the step 120. Accordingly, in some embodiments, a single staircase (e.g., the descending staircase 136, the ascending staircase 138) or the staircases of a single set of staircases may include any combination of steps 120 with metal oxide regions 122 and steps 120 without metal oxide regions 122.

For an individual stadium 140 (FIG. 1) (e.g., multi-series stadium 150 (FIG. 4), single-series stadium 152 (FIG. 5), single-series stadium 152′ (FIG. 6)), the number of steps 120 in the descending staircase 136 thereof may or may not be the same as the number of steps 120 in the ascending staircase 138 thereof. In other embodiments, the series of steps 120 of any individual stadium 140 (FIG. 1) (e.g., multi-series stadium 150 (FIG. 4), single-series stadium 152 (FIG. 5), single-series stadium 152′ (FIG. 6)) may be provided by a single descending staircase 136 or single ascending staircase 138, rather than each staircase set including at least one descending staircase 136 and at least one ascending staircase 138. In such embodiments, the half-stadium offset 156 may be omitted.

With returned reference to FIG. 1, in some embodiments, the relatively lower stadiums 140 of the block 116 may be configured as the single-series stadium 152 of FIG. 5 and/or the single-series stadium 152′ of FIG. 6. That is, the relatively higher stadiums 140 of the block 116 may be configured as the multi-series stadium 150 of FIG. 4. It may be relatively more challenging to accurately form and extend, to relatively lower levels of the stack 102, the staircases of the multi-series stadiums 150 than to accurately form and extend, to the relatively lower levels of the stack 102, the staircases of the single-series stadiums 152 (FIG. 5). Accordingly, in some embodiments, such as illustrated in FIG. 1, the multi-series stadium 150 architecture is used for relatively elevationally higher stadiums 140 (e.g., those illustrated in first stadium area 160 and second stadium area 162 of FIG. 1) of the block 116, while the single-series stadium 152 (or the single-series stadium 152′ of FIG. 6) architecture is used for relatively elevationally lower stadiums 140 (e.g., those illustrated in third stadium area 164 and fourth stadium area 166 of FIG. 1) of the block 116. In some embodiments, the stadiums 140 in the upper about two-thirds of the stack 102 are multi-series stadiums 150, and the stadiums 140 in the lower about one-third of the stack 102 are single-series stadiums 152 (FIG. 5) or single-series stadiums 152′ (FIG. 6).

Though FIG. 1 illustrates the second stadium area 162 as being to the right of the first stadium area 160, the third stadium area 164 as being to the right of the second stadium area 162, and the fourth stadium area 166 as being to the right of the third stadium area 164, the disclosure is not so limited. There may be one or more additional stadiums 140 disposed between the illustrated stadium areas (between the first stadium area 160 and the second stadium area 162, between the second stadium area 162 and the third stadium area 164, between the third stadium area 164 and the fourth stadium area 166), such as in non-illustrated portions generally represented by intermediate regions 168. Additionally or alternatively, one or more additional stadiums 140 may be disposed laterally adjacent to the first stadium area 160 and/or the fourth stadium area 166. Any such additional stadiums 140, whether interspersed with the stadiums 140 illustrated in FIG. 1 or adjacent to the stadiums 140 illustrated in FIG. 1, may be structured as the multi-series stadium 150 (FIG. 4), the single-series stadium 152 (FIG. 5), the single-series stadium 152′ (FIG. 6), or as differently-structured stadiums and either with or without metal oxide regions 122 in the steps 120 and either with or without through-step contacts 130. Any such additional stadiums 140 may also be within the elevations of the stack 102 as illustrated in FIG. 1 or within other elevations of the stack 102 not illustrated in FIG. 1, such as in higher-still elevations of the stack 102 formed over the illustrated tiers 108, or such as in lower-still elevations of the stack 102 formed between the illustrated tiers 108 and the base structure 112.

The lateral order (e.g., lateral arrangement) of the first stadium area 160, the second stadium area 162, the third stadium area 164, and the fourth stadium area 166 may be other than that illustrated in FIG. 1. For example, relatively elevationally lower stadiums 140 (e.g., the stadiums 140 illustrated in the third stadium area 164 and the fourth stadium area 166) may be to the left side of relatively elevationally higher stadiums 140 (e.g., the stadiums 140 illustrated in the first stadium area 160 and the second stadium area 162); and/or one or more relatively lower stadiums 140 may be laterally between relatively higher stadiums 140, and/or vice versa.

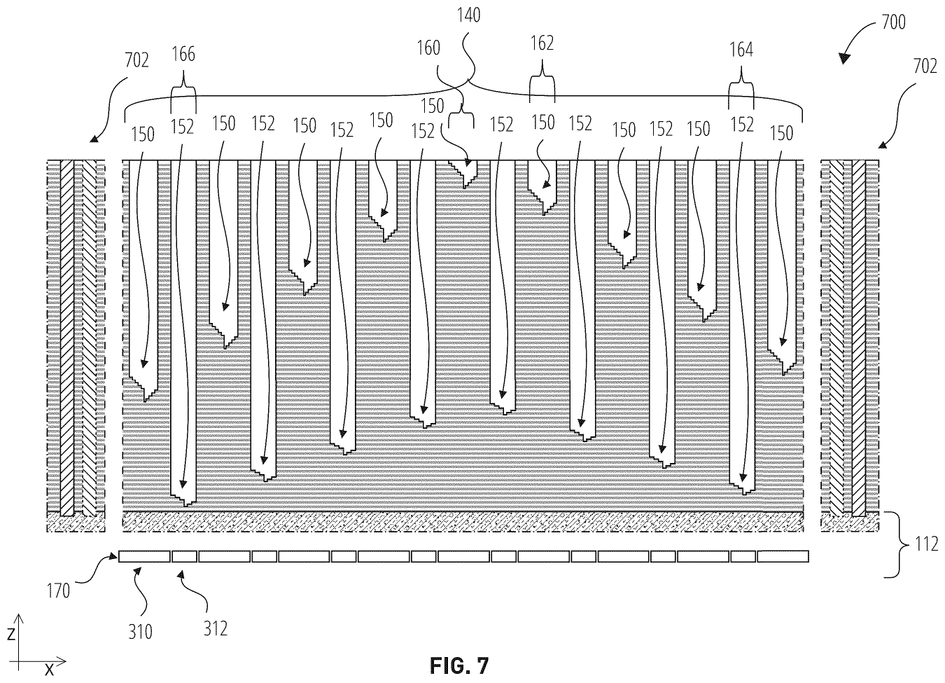

In some embodiments, such as that illustrated in FIG. 7, a microelectronic device structure 700—which may include the stadiums 140 of the microelectronic device structure 100 of FIG. 1—may be fabricated and structured so that the elevationally lower stadiums 140 of the single-series stadium 152 (FIG. 5) or of the single-series stadium 152′ (FIG. 6) architecture alternate, across the width of the block 116 (FIG. 1), with the elevationally higher stadiums 140 of the multi-series stadium 150 (FIG. 4) architecture. Accordingly, the stadiums 140 may be substantially symmetrically distributed across the width of the series of stadiums 140 (e.g., across the width of the block 116 (FIG. 1)) and between array portions 702 disposed to the lateral sides of the stadiums 140 series. The array portions 702 may include the aforementioned array(s) of pillars (e.g., including channel material and memory material) that extend through the stack 102 and effectuate the formation of strings of memory cells. In some embodiments, non-functional (e.g., so-called “dummy”) pillars are also included in the array portions 702. For example, dummy pillars may be horizontally between the functional pillars (e.g., forming the strings of memory cells) and the stadiums 140.

The microelectronic device structure 100 may also include string drivers 170 (e.g., access line drivers, word line drivers) configured to selectively supply access signals, such as programming signals (e.g., programming voltages) to the conductive structures 106 (e.g., to access lines, also known as “word lines”) at particular levels of the stack 102 so as to access (e.g., program) the memory cell(s) (e.g., in the array portions 702 (FIG. 7)) that are operatively associated with respective conductive structures 106. There may be one string driver 170 coupled to one respective conductive structure 106 (e.g., access line), such that the microelectronic device structure 100 may include one string driver 170 for each respective conductive structure 106 to which a line contact 118 (FIG. 1) extends.

The string drivers 170 operatively associated with the conductive structures 106 of a particular block 116 (FIG. 1) may be disposed below the stack 102 (FIG. 1) of the block 116 (e.g., such as in or under the base structure 112, as schematically illustrated in FIG. 7 and FIG. 1), may be disposed above the stack 102 of the block 116, and/or within other areas of the microelectronic device structure 100 (FIG. 1).

Because the multi-series stadiums 150 accommodate relatively more line contacts 118 than the single-series stadiums 152 (or the single-series stadium 152′ (FIG. 6)), there may be relatively more string drivers 170 operatively associated with individual multi-series stadiums 150 than with individual single-series stadiums 152.

In embodiments in which the stadiums 140 are arranged with multi-series stadiums 150 laterally interspersed with single-series stadiums 152 (or single-series stadium 152′ (FIG. 6)), the string drivers 170 operatively associated with the single-series stadiums 152 (or the single-series stadiums 152′ (FIG. 6)) may be interspersed with string drivers 310 operatively associated with the multi-series stadiums 150.

With returned reference to FIG. 3A, a series of string drivers 170 is illustrated with electrical connections to corresponding line contacts 118 leading to the stadiums 140. The string drivers 170 of FIG. 3A are illustrated as outside of horizontal areas of the blocks 116 for ease of illustration only. The string drivers 170 may be disposed at least partially within horizontal areas of the blocks 116, and they may be positioned vertically underneath the blocks 116, vertically above the blocks 116, or some combination thereof. The string drivers 170 (e.g., the string drivers 310 for the multi-series stadiums 150; the string drivers 312 for the single-series stadiums 152 (or single-series stadium 152′ (FIG. 6))) may be arranged in one or more series (e.g., rows).

The string drivers 170 may be in operative communication with the line contacts 118 via one or more conductive lines (e.g., circuitry 314), as illustrated in FIG. 3A. The circuitry 314 of FIG. 3A is schematically illustrated, and the disclosure is not limited to the particular geometry of the circuitry 314 illustrated. Via the circuitry 314 and the line contacts 118 (e.g., the to-step contacts 124 that extend to the steps 120, and the through-step contacts 130 that extend to and through the steps 120 within the metal oxide regions 122, as illustrated in FIG. 3B), the string drivers 170 may be in operative communication with the conductive structures 106 providing the steps 120 (e.g., with electrical communication via the to-step contacts 124) and with the conductive structures 106 below the steps 120 (e.g., with electrical communication via the through-step contacts 130).

Accordingly, disclosed is a microelectronic device comprising a stack and a staircased stadium within the stack. The stack comprises a vertically alternating sequence of insulative structures and conductive structures arranged in tiers. The staircased stadium comprises steps at different tier elevations of a group of the tiers. The steps comprise treads. Each of the treads is provided by an upper surface area of one of the conductive structures within the group of the tiers and by an upper surface area of a metal oxide region extending through the one of the conductive structures. A pair of conductive contact structures extends to one of the steps. The pair of conductive contact structures comprises a first conductive contact structure and a second conductive contact structure. The first conductive contact structure terminates at the tread of the one of the steps within the upper surface area of the one of the conductive structures. The second conductive contact structure extends through the tread of the one of the steps within the upper surface area of the metal oxide region.

Also disclosed is a microelectronic device comprising a stack structure and a series of stadiums within the stack structure. The stack structure comprises a vertically alternating sequence of insulative structures and conductive structures arranged in tiers. In the series of stadiums, each of at least some of the stadiums comprises at least one staircase defined in a group of the tiers. The group of the tiers comprises treaded tiers and covered tiers. The conductive structures of the treaded tiers provide treads of steps of the at least one staircase. The conductive structures of the covered tiers are each directly vertically below one of the treaded tiers. Metal oxide regions extend through the conductive structures of the treaded tiers. At least one conductive contact structure extends to one of the conductive structures providing one of the treads. At least one other conductive contact structure extends through one of the metal oxide regions. The one of the metal oxide regions is in the one of the conductive structures providing the one of the treads. The at least one other conductive contact structure further extends to one of the conductive structures of the covered tiers.

Microelectronic devices (e.g., microelectronic devices including the microelectronic device structure 100 of any or all of FIG. 1 through FIG. 7) may be formed by methods in which portions of the conductive structures 106 exposed to provide steps 120 are converted from conductive metal-including material(s) to non-conductive (e.g., insulative) metal-oxide-including material(s), forming the metal oxide regions 122 of the steps 120 through which the through-step contacts 130 are subsequently formed to extend. By forming the metal oxide regions 122 via a metal-to-oxide conversion technique, the metal oxide regions 122 may be accurately and consistently fabricated, even when simultaneously forming the metal oxide regions 122 of relatively higher elevation steps 120 and relatively lower elevation steps 120.

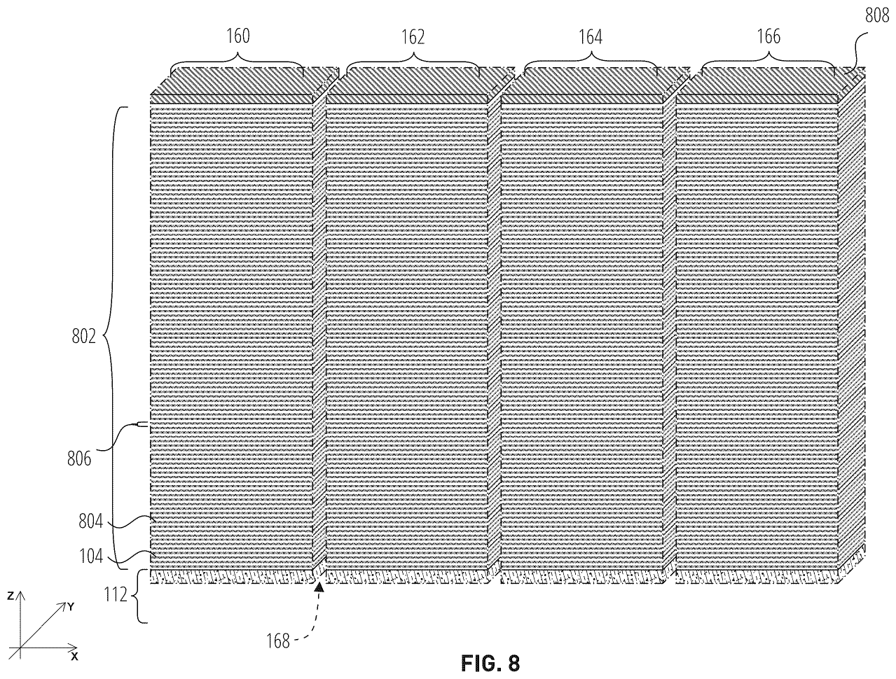

With reference to FIG. 8 through FIG. 28, illustrated are various stages of forming a microelectronic device (e.g., including any or all of the structures illustrated in FIG. 1 through FIG. 7). Referring to FIG. 8, a stack 802 (otherwise referred to herein as a “stack structure” or “tiered stack”) is formed on the base structure 112, including in areas (e.g., the first stadium area 160, the second stadium area 162, the third stadium area 164, and the fourth stadium area 166 previously described with reference to FIG. 1) in which the stadiums 140 (FIG. 1) will be formed.

The stack 802 includes a vertically alternating sequence of the insulative structures 104 and sacrificial structures 804 arranged in tiers 806. The sacrificial structures 804 will eventually be replaced with, or otherwise converted into, the conductive structures 106 (e.g., FIG. 1). In other embodiments, the stack 802 may be formed to include the conductive structures 106 instead of the sacrificial structures 804, even without replacement or conversion, such that the stack 802 may have substantially the materials of the stack 102 of FIG. 1. Accordingly, the stack 802 is formed to include the insulative structures 104 and “other structures,” which other structures may be either the sacrificial structures 804, in embodiments including subsequent replacement or conversion to the conductive structures 106, or the conductive structures 106, in embodiments not including subsequent replacement or conversion.

To form the stack 802, formation (e.g., deposition) of the insulative structures 104 may be alternated with formation (e.g., deposition) of the other structures (e.g., the sacrificial structures 804). In some embodiments, the stack 802 is formed, at this stage, to include as many tiers 806 with the sacrificial structures 804 as there will be tiers 108 (FIG. 1) with conductive structures 106 (FIG. 1) in the final microelectronic device structure (e.g., the microelectronic device structure 100 of FIG. 1 and/or the microelectronic device structure 700 of FIG. 7).

One or more masks 808 (e.g., hardmasks) may also be included on (e.g., above) the stack 802 and utilized in subsequent material-removal (e.g., etching, patterning) processes.

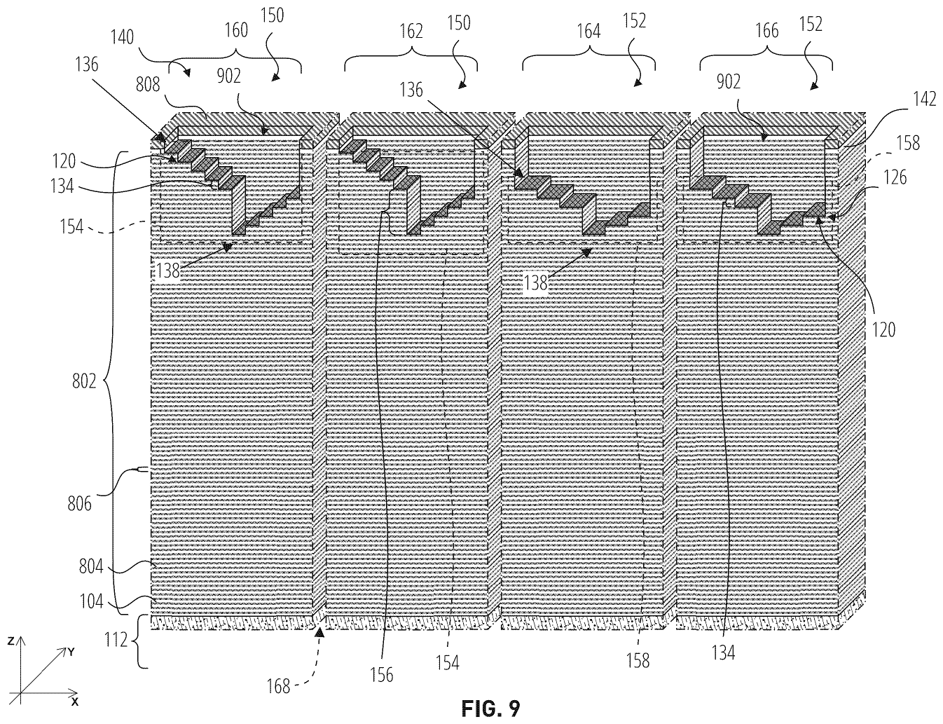

With reference to FIG. 9, the stack 802 (and the mask 808) may be patterned—in a series of material-removal (etching) and mask 808 trimming stages—to form, in substantially the same uppermost group of tier 108 elevations, the staircase profiles of each of the stadiums 140 (e.g., the staircase profile of the multi-series stadiums 150 and the single-series stadiums 152 (and/or single-series stadiums 152′ (FIG. 6))) in the respective footprint (e.g., horizontal) areas (e.g., the first stadium area 160, the second stadium area 162, the third stadium area 164, the fourth stadium area 166). Areas of the stack 802 for the crests 142 and the bridges 144 (FIG. 1) may not be etched so that these portions of the stack 802 retain the full, initial height of the stack 802.

For example, the descending staircase 136 and the ascending staircase 138 of each set of staircases may be initially formed as two opposing, mirrored staircases, such as by a sequence of material-removal (e.g., etching) acts by which the mask 808 is patterned to define, for each such pair of staircases, an opening of a first width (e.g., a width of about two steps 120) that is then patterned into the stack 102 the depth of the riser height 134 (e.g., two tiers 806 deep). Then, the mask 808 may be trimmed to expand the opening to a second width (e.g., a width of about four steps 120) that is then patterned into the stack 102 the depth of the riser height 134 (e.g., two tiers 806 deep), further lowering the first opening to two times (2×) the riser height 134 deep. Then, the mask 808 may be trimmed to expand the opening to a third width (e.g., a width of about sixth steps 120), which third-width opening is then patterned the riser height 134, further lowering the first opening to a depth of three times (3×) the riser height 134 and further lowering the second opening to a depth of two times (2×) the riser height 134. This may be repeated until completing the profiles of the initial descending staircase 136 and ascending staircase 138 that are opposing and mirrored. Then, a lateral half of each stadium 140 may be covered (e.g., filled with sacrificial material(s) and/or re-masked) and one of the two staircases may be patterned into the stack 102 the depth of the half-stadium offset 156 to vertically offset the lower of the two staircases (e.g., to lower the ascending staircase 138) from the other (e.g., the descending staircase 136). The half-stadium offset 156 may complete the formation of the profiles of the stadiums 140 (e.g., the multi-series stadiums 150, the single-series stadiums 152 (and/or the single-series stadiums 152′ (FIG. 6))) through substantially the same uppermost elevations of the stack 102 and with the staircases (e.g., the descending staircases 136, the ascending staircases 138) at the base of initial stadium openings 902.

As used herein, the term “stadium opening” (e.g., as in the initial stadium openings 902) means and includes an opening that has, along the width (X-axis dimension) of its base, the profiles of the set of staircases (e.g., the descending staircase 136 and the ascending staircase 138). Accordingly, the initial stadium openings 902 expose surfaces (e.g., step 120 treads) of the sacrificial structures 804 at different tier 806 elevations throughout the height of the staircases.

At this stage, the vertically highest of the multi-series stadiums 150 may already be at its final elevations in the stack 802, and so the depth extension to form the half-stadium offset 156 may complete the formation of that multi-series stadium 150, e.g., in the first stadium area 160. Contrarily, the others of the multi-series stadiums 150 may not yet be at their final elevations in the stack 802. Also, at this stage, the staircase profiles for the single-series stadiums 152 (and/or single-series stadiums 152′ (FIG. 6)) may not yet be at their final elevations, such as in embodiments in which the single-series stadiums 152 (or single-series stadiums 152′ (FIG. 6)) are reserved for the vertically lowest of the stadiums 140.

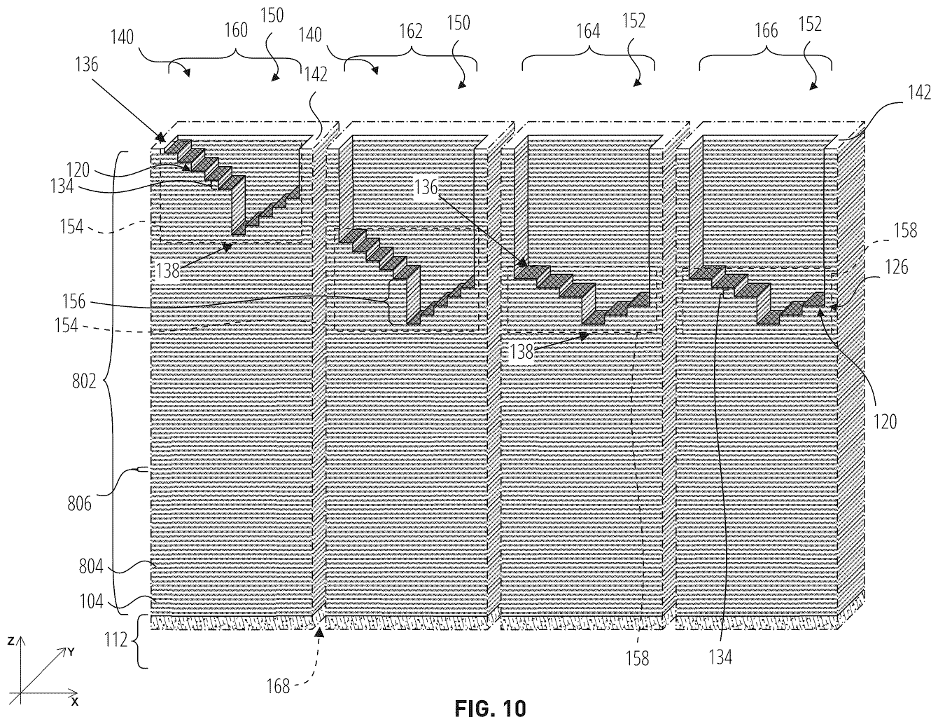

As illustrated in FIG. 10, the staircase profile of the second stadium area 162 may be extended to its final elevations, to form the multi-series stadium 150 in the second stadium area 162 of FIG. 1. Concurrently, the staircase profiles in the third stadium area 164 and the fourth stadium area 166 may be extended downward a substantially equal number of tiers. During this stage, the already-completed stadium 140 in the first stadium area 160 may not be exposed (e.g., may be covered by fill material and/or the mask 808 (FIG. 9)). Accordingly, though not illustrated in FIG. 9, the mask 808 from the stage of FIG. 9 may not be completely removed and/or may be at least partially reformed and/or re-patterned prior to the stage illustrated in FIG. 10.

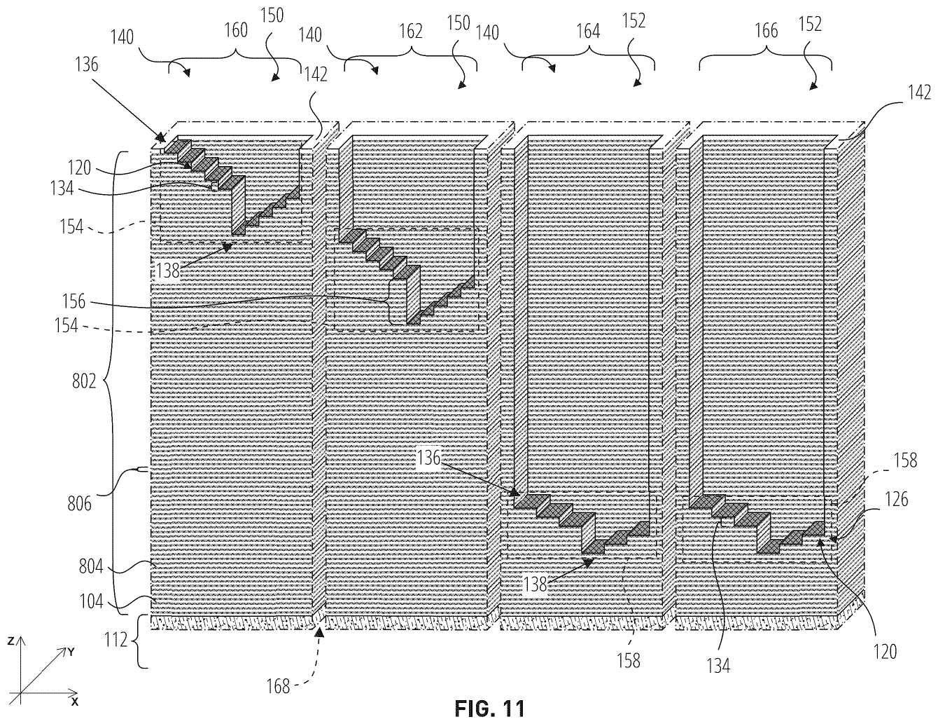

Thereafter, the staircase profile extensions may be continued downward in a sequence of depth-extension stages, for the not-yet-at-final-depth stadiums 140 (in the third stadium area 164 and the fourth stadium area 166) to lower the staircase profiles of the remaining stadiums 140 to their final elevations. For example, the staircases of the single-series stadiums 152 (or single-series stadiums 152′ (FIG. 6)) in the third stadium area 164 and the fourth stadium area 166 may be concurrently extended to the final elevations of the single-series stadium 152, as illustrated in FIG. 11 (e.g., while the multi-series stadiums 150 in the first stadium area 160 and the second stadium area 162 are filled and/or otherwise covered).

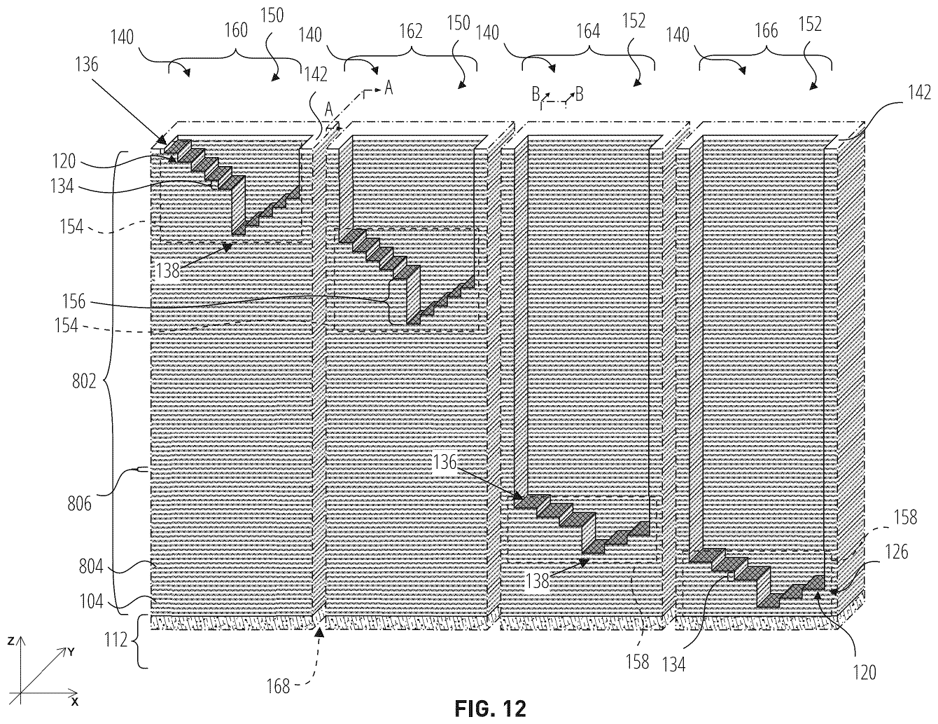

Then, the single-series stadium 152 in the fourth stadium area 166 may be extended to its final elevations, as illustrated in FIG. 12 (e.g., while the other stadiums 140, already at their final elevations, are filled and/or otherwise covered).

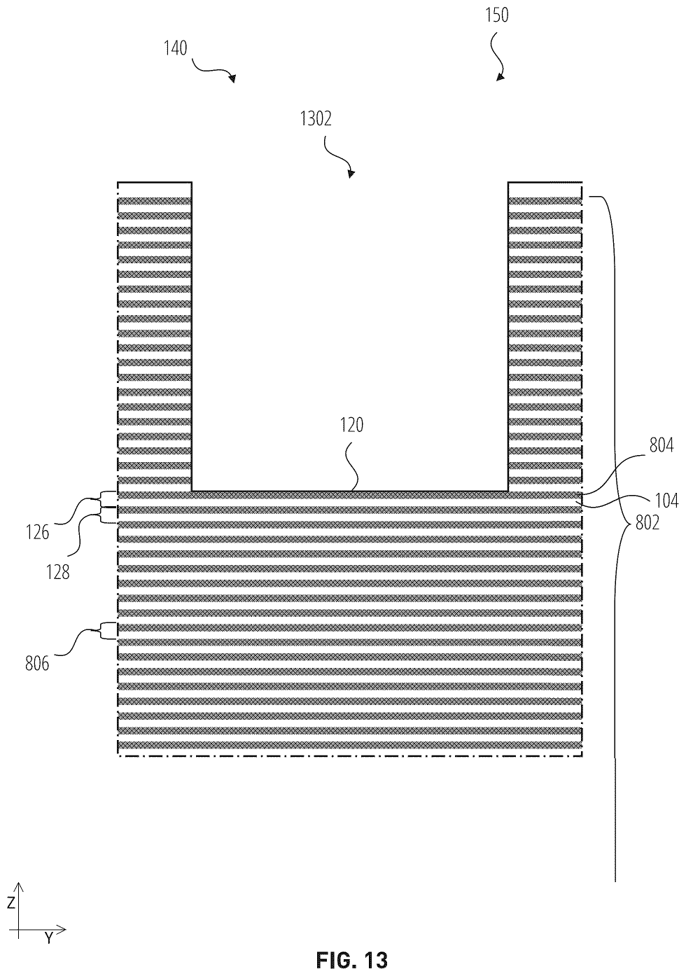

FIG. 13 illustrates a view along section line A-A of FIG. 12 of at least an uppermost portion of the stack 802, showing one of the completed steps 120 at the base of one of the stadium openings 1302 (e.g., an uppermost step of the descending staircase 136 of the multi-series stadium 150 in the second stadium area 162 of FIG. 12). At this stage (e.g., completion of the stage of FIG. 12), each step 120 exposes an upper surface area of one of the sacrificial structures 804, namely, the sacrificial structure 804 that is within the treaded tier 126.

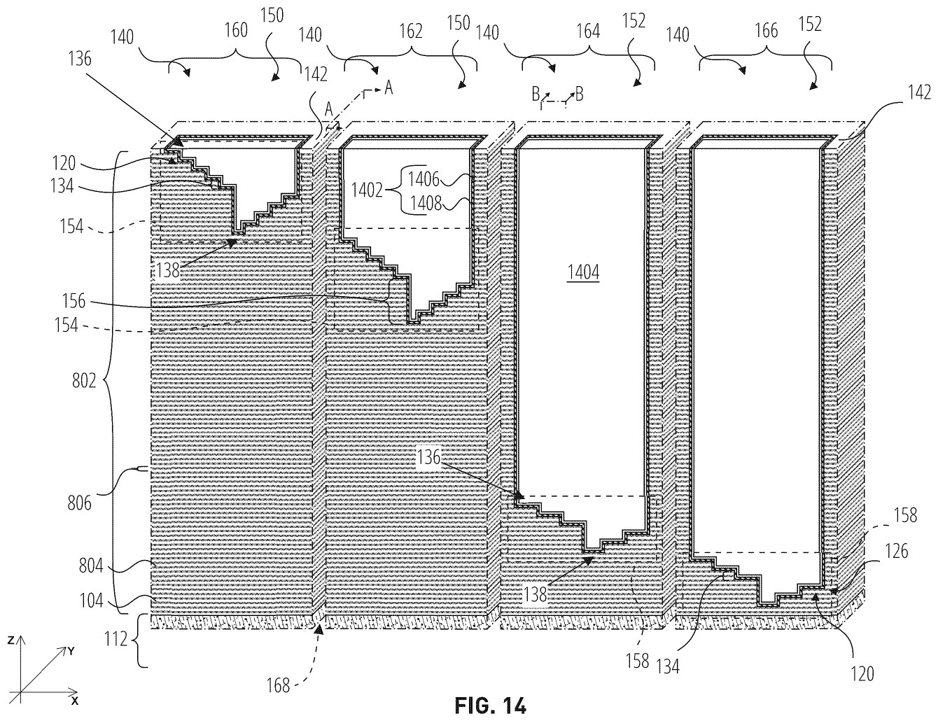

With reference to FIG. 14, at least one dielectric liner(s) 1402 may be formed (e.g., conformally deposited) in the stadium openings to substantially line the exposed surfaces of the tiers 806. One or more insulative fill material(s) 1404 (e.g., dielectric material(s)) may be formed (e.g., deposited) in the stadium openings 1302, on the dielectric liner(s) 1402 to substantially fill the remaining space (e.g., of the stadium openings 1302) above each of the completed stadiums 140.

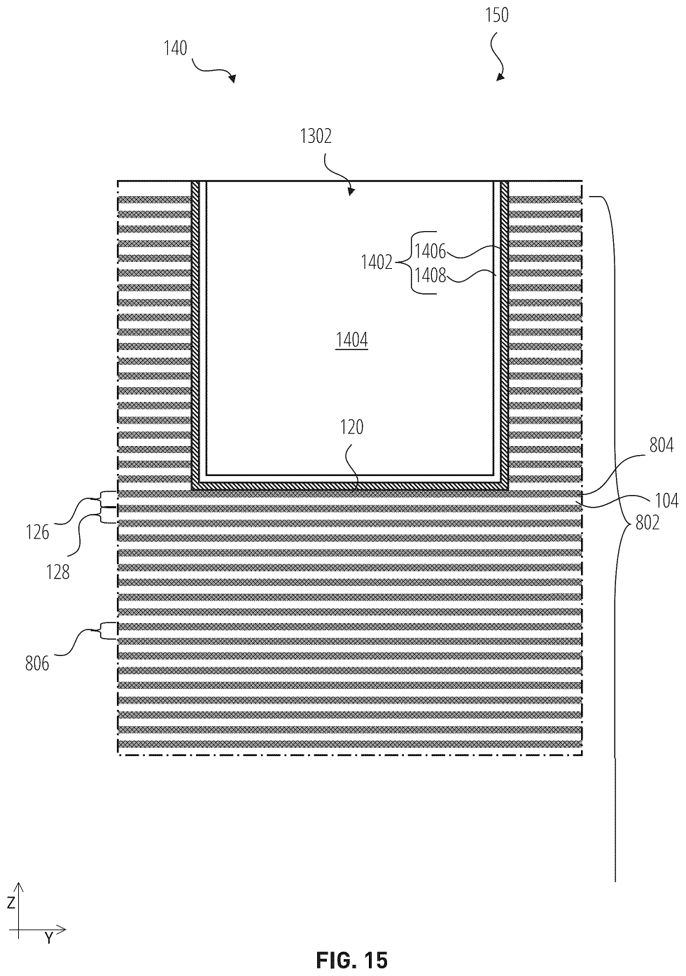

FIG. 15 illustrates a view along section line A-A of FIG. 14 to more clearly show the dielectric liner(s) 1402. In some embodiments, the dielectric liner(s) 1402 include a dielectric liner 1406 directly on the sidewalls and horizontal surfaces of the tiers 806 (e.g., directly on the staircases and their steps 120 that define the stadium openings 1302) and an additional dielectric liner 1408 directly on the dielectric liner 1406.

The material of the dielectric liner 1406, formed directly on the exposed surfaces of the tiers 806, may be formed of and include an insulative material, such as a dielectric oxide material (e.g., silicon dioxide) that is selectively removable relative to the material of the sacrificial structures 804 of the tiers 806.

The additional dielectric liner 1408 may be formed of and include another insulative material, such as a dielectric nitride material (e.g., silicon nitride) or a silicon material (e.g., polysilicon), relative to which the insulative fill materials 1404 may be selectively removed.

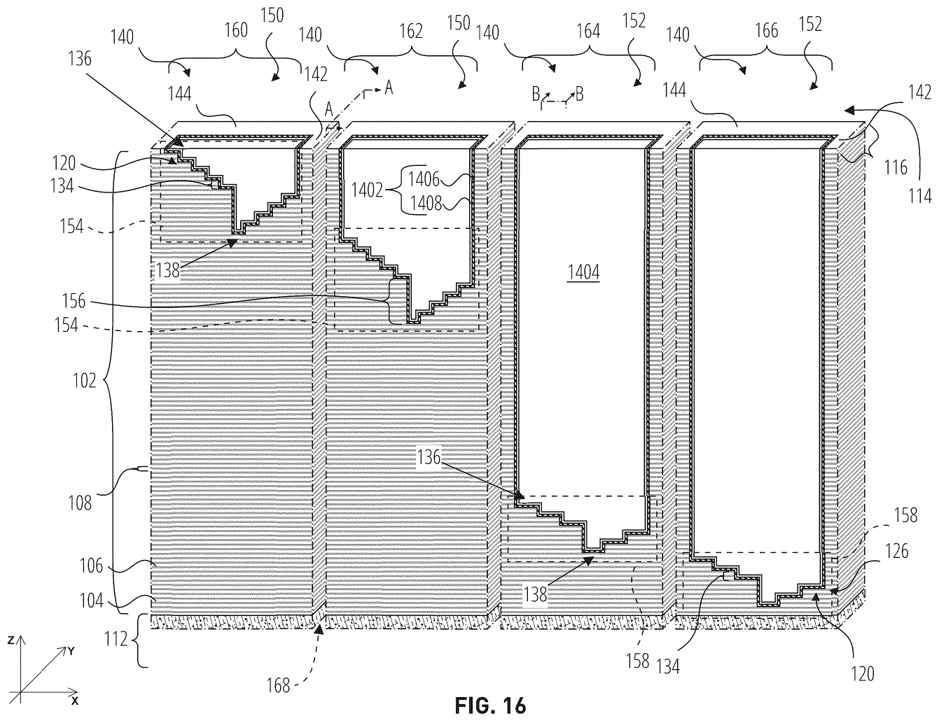

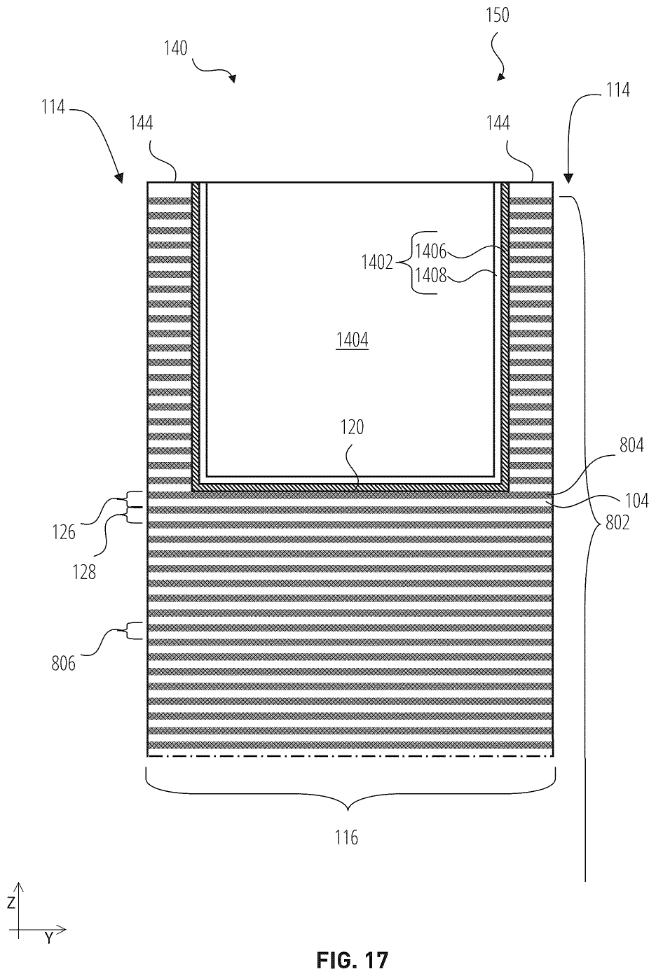

With reference to FIG. 16 and FIG. 17 (which is a view along section line A-A of FIG. 16), the slits 114 may be formed (e.g., etched) through a whole height of the stack 802 (FIG. 14 and FIG. 15) to divide the stack 802 into the blocks 116. Forming the slits 114 also defines the bridges 144 at least one of the rear side and the front side of the stadiums 140.

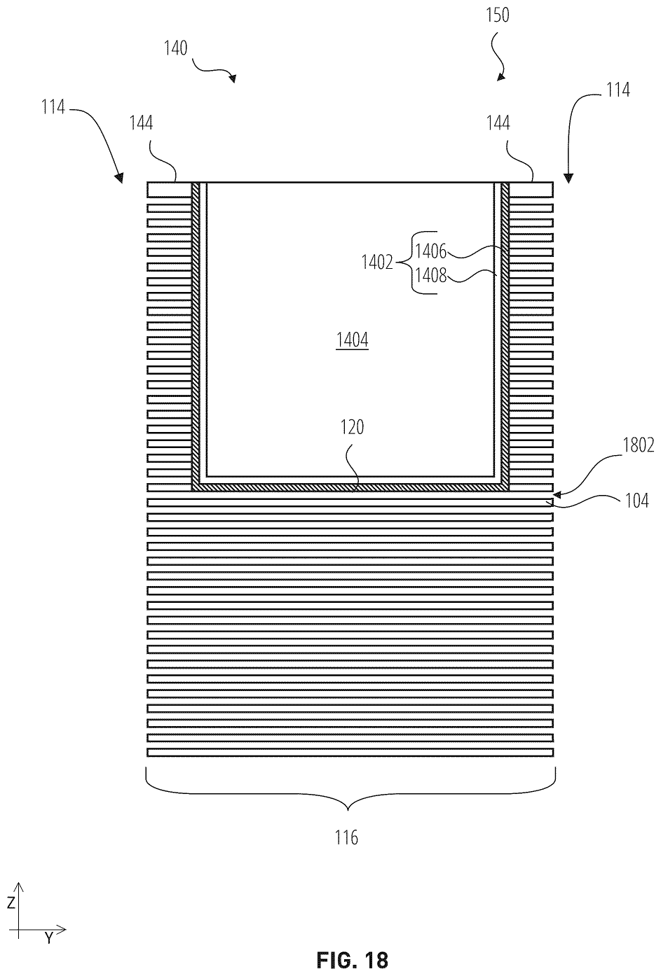

In embodiments in which the stack 802 (FIG. 8) was formed to include sacrificial structures 804 (FIG. 12) that are not yet configured as the conductive structures 106, the sacrificial structures 804 may be substantially removed (e.g., exhumed)—by way of the slits 114—without substantially removing the insulative structures 104 or the dielectric liner 1406. The substantial removal of the sacrificial structures 804 provides—as illustrated in FIG. 18—voids 1802 vertically alternating with the insulative structures 104. The insulative structures 104 may remain at substantially their initial elevations due to, e.g., support from other structures (e.g., support pillars) previously formed in the fabrication process. For ease of illustration such supportive structures are not illustrated in the figures.

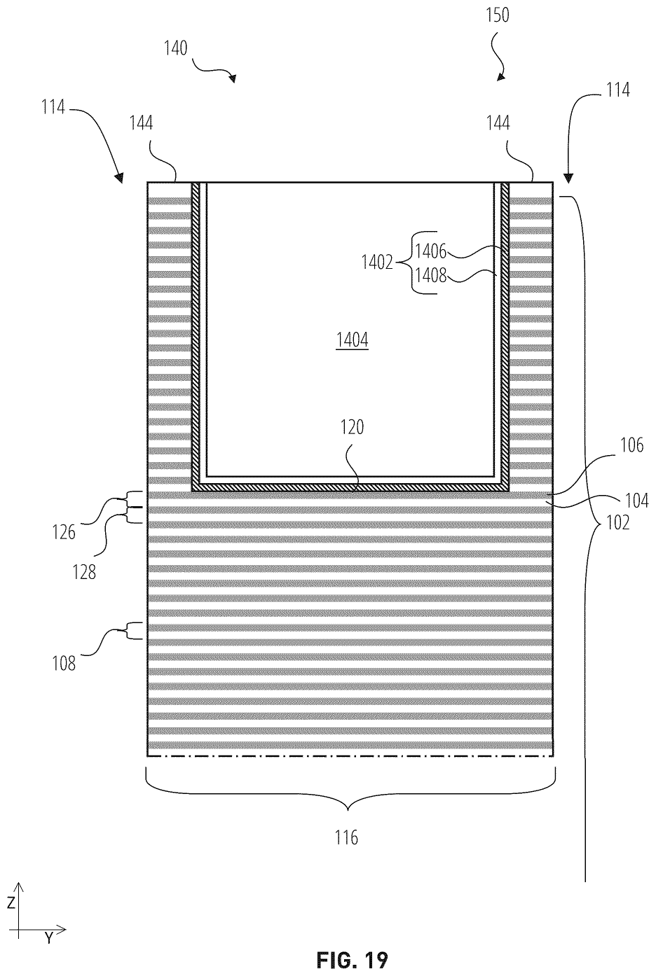

With reference to FIG. 19, the conductive material(s) of the conductive structures 106 may then be formed in the voids 1802 (FIG. 18) to complete the formation of the stack 102 with the conductive structures 106 interleaved with the insulative structures 104.

In other embodiments, the sacrificial structures 804 of FIG. 16 and FIG. 17 are not substantially removed (such that the stage of FIG. 18 may be omitted), but are chemically converted to form the conductive material(s) of the conductive structure 106 to complete the formation of the stack 102.

By the replacement or conversion process, the stadiums 140 then include the steps 120 at exposed upper surface areas of the conductive structures 106 of the treaded tiers 126.

The non-conductive material(s) 302 (FIG. 3A) may be formed (e.g., deposited) to fill the slits 114, to form slit structures between the blocks 116, as illustrated in FIG. 3A.

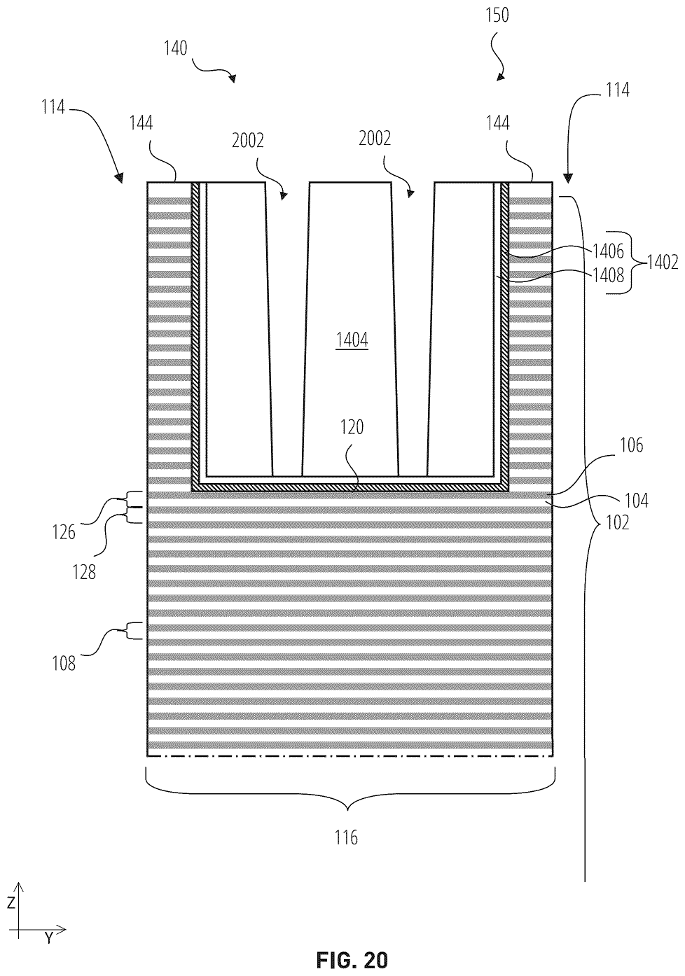

With reference to FIG. 20, initial contact openings 2002—one for each line contact 118 (FIG. 1) to be formed—may be formed (e.g., etched) through at least the insulative fill material(s) 1404. The dielectric liner(s) 1402 may function as “etch stop” materials for this process, and the initial contact openings 2002 may terminate on or in any of the dielectric liner(s) 1402.

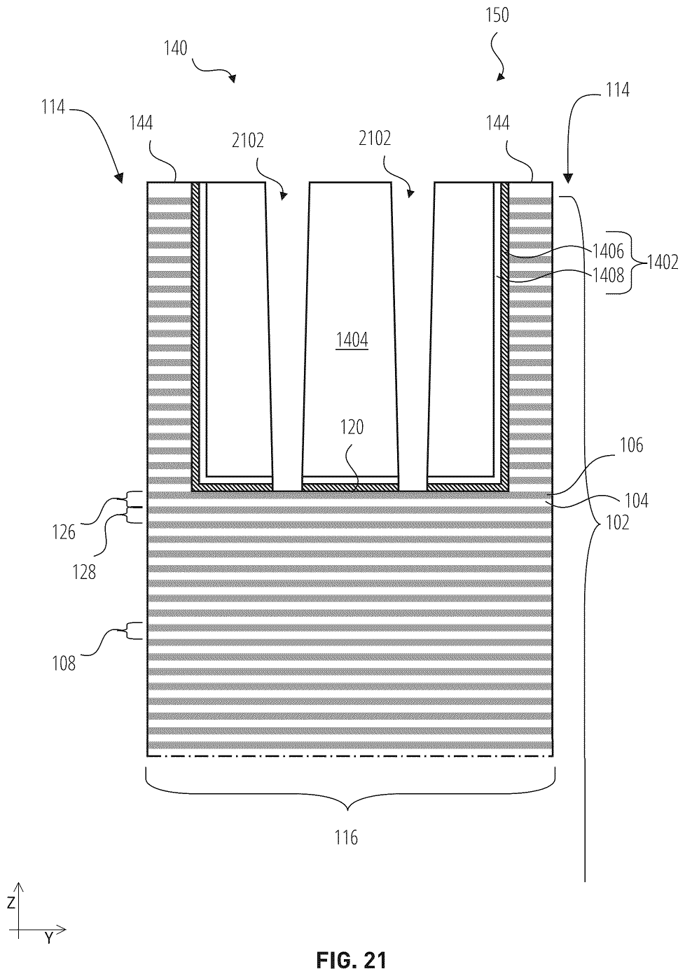

In embodiments in which the initial contact openings 2002 terminate on or in the dielectric liner(s) 1402, the material(s) of the dielectric liner(s) 1402 may then be etched where exposed to extend the initial contact openings 2002 to form contact openings 2102, as illustrated in FIG. 21, that terminate on or in the conductive structure 106 of the treaded tier 126.

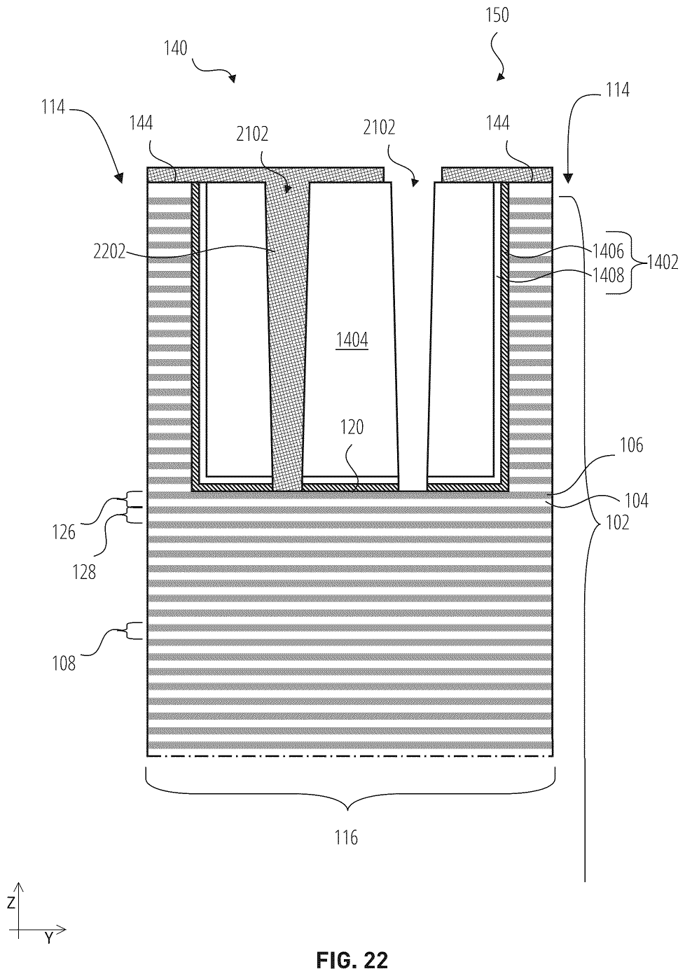

With reference to FIG. 22, one or more sacrificial fill material(s) 2202 may be formed on or over the contact openings 2102 where the to-step contacts 124 (FIG. 1) are to be formed, leaving exposed other contact openings 2102 where the through-step contacts 130 (FIG. 1) are to be formed.

In some embodiments, the sacrificial fill material(s) 2202 may be formed of and include a negative tone resist material. Such sacrificial fill material(s) 2202 may be formed to initially substantially fill all contact openings 2102, selectively exposed at least in the areas for the to-step contacts 124 (FIG. 1), and the non-exposed areas removed to re-open the contact openings 2102 for the through-step contacts 130 (FIG. 1).

In other embodiments, the sacrificial fill material(s) 2202 may be formed of and include a positive tone resist material, and the select exposure thereof may be of those areas corresponding to the contact openings 2102 for the through-step contacts 130 before those contact openings 2102 are re-opened.

In still other embodiments, the sacrificial fill material(s) 2202 may be formed of and include a non-conformal material, such as a carbon-based mask material, a silicon-based mask material, and the sacrificial fill material(s) 2202 may be formed (or formed and patterned) to be present substantially only over the contact openings 2102 for the to-step contacts 124 (FIG. 1).

With substantially only the contact openings 2102 for the through-step contacts 130 (FIG. 1) remaining open, exposed in each still-open contact opening 2102 is an area of the conductive structure 106 of the treaded tier 126. The exposed area of the conductive structure 106 may be an upper surface area in embodiments in which the contact openings 2102 terminate at, but do not extend into or through the conductive structure 106 of the treaded tier 126. In other embodiments, the contact openings 2102 may extend into or through the conductive structure 106 of the treaded tier 126, such that the exposed area(s) at the base of the still-open contact openings 2102 may include sidewall surface(s) of the conductive structure conductive structures 106 of the treaded tiers 126. Whether the contact openings 2102 extend to, into, or through the conductive structures 106 of the treaded tiers 126, the contact openings 2102 may not extend so far as to expose any of the conductive structures 106 of the covered tiers 128.

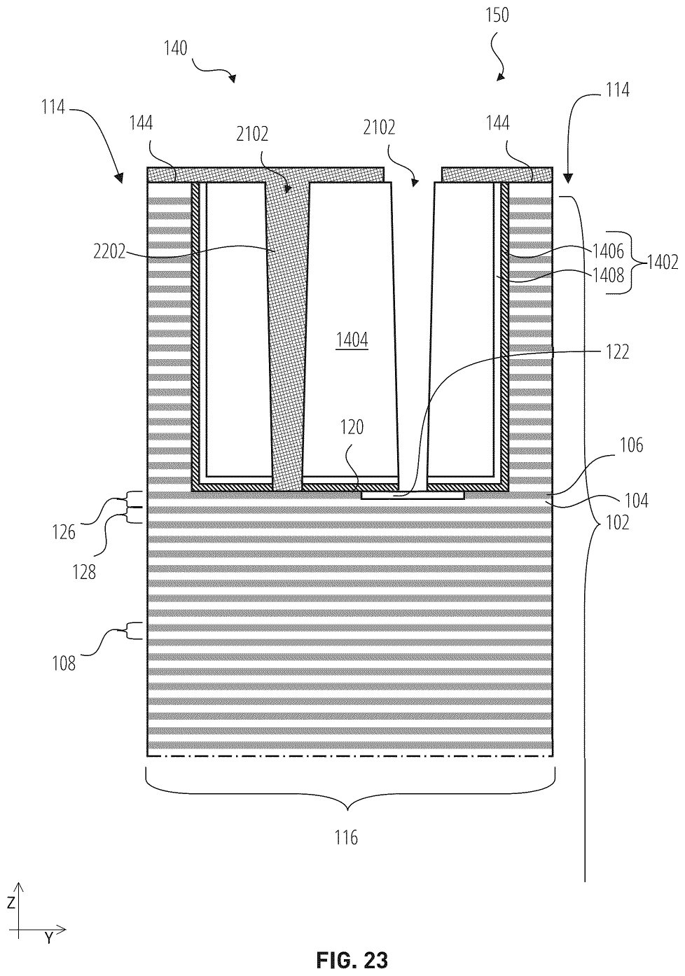

Oxidation process(es) are then performed to introduce oxygen into the exposed region of the conductive structure 106, converting the conductive material(s) (e.g., conductive metal-including material(s)) of the exposed area of the conductive structure 106 into the non-conductive metal-oxide material(s) of the metal oxide regions 122, as illustrated in FIG. 23. The duration and/or conditions of the oxidation process(es) may be controlled to tailor the dimensions (e.g., diameter) of the metal oxide region 122 to be sufficiently large enough to provide electrical isolation between the still-conductive material(s) of the conductive structure 106 of the treaded tier 126 and the through-step contact 130 (FIG. 1) to be subsequently formed. For example, the metal oxide region 122 may have a diameter of at least about twenty nanometers (20 nm), at least about 50 nm, at least about 150 nm, at least about 200 nm, or at least about 300 nm up to about 500 nm.

The oxidation process(es) may include one or more techniques to implant, drive, or otherwise add oxygen into the exposed area of the conductive structure 106 and its immediately-surrounding areas. In some embodiments, the oxidation process includes a wet oxidation process (e.g., introducing an oxidizing chemistry with oxygen radicals or other source of oxygen ions), a dry oxidation process (e.g., introducing O₃ (ozone) at temperatures of at least about 500° C.), or another oxidation process. For example, in some embodiments using a wet oxidation process, the oxidizing chemistry includes H₂O, O₂, and/or CF₄—either introduced together or separately—at temperatures of about 180° C. As another example, in other embodiments using a wet oxidation process, the oxidizing chemistry includes O₂ and/or H₂N₂—either introduced together or separately—at temperatures controlled to facilitate oxidation.

The oxidized material forming the metal oxide region 122 may extend horizontally beyond the area exposed at the base of the contact opening 2102, as illustrated in FIG. 23. In some embodiments, the volume of material in the metal oxide region 122 may be relatively expanded, and the metal-oxide material of the metal oxide region 122 may expand upward into the contact opening 2102 at this stage. In other embodiments, the metal oxide region 122 does not expand upward into the contact opening 2102 at this stage.

Forming the metal oxide region 122 by the oxidation process(es)—rather than, e.g., process(es) that may involve partial removal (e.g., etching) of the conductive structures 106—may form the metal oxide region 122 relatively accurately and consistently at the base of each of the still-open contact openings 2102, regardless of the aspect ratio of the still-open contact opening 2102 and the elevation of the stack 102 occupied by the conductive structure 106 partially exposed at the base of the still-open contact opening 2102.

For example, by forming the metal oxide regions 122 by adding oxygen into the already-formed conductive structures 106 without removing portions of the conductive structure 106, material-removal acts (e.g., etching acts) may be avoided, which material-removal acts may otherwise cause deformations or other fabrication inconsistencies. For example, in forming the conductive structures 106 in place of the initial sacrificial structures 804 (FIG. 8) as described above with regard to FIG. 18 and FIG. 19, the conductive material(s) of the conductive structures 106 may—however inadvertently—form with so-called “seams” between layers of conformally deposited conductive material(s). Exposing such seam-including conductive structures to etchant(s)—e.g., via the contact openings 2102 so as to remove a portion of the conductive structure 106 before forming oxide material(s) in its place—may result in the etchants accessing the “seams” and removing more of the conductive material(s) than intended. This unintended over-etching may be more pronounced for steps 120 at the base of shallower stadium openings 1302 (FIG. 13), compared to the steps 120 at the base of deeper stadium openings 1302 (FIG. 13). Consequently, conductive structures inadvertently formed with seams (e.g., in elevationally higher stadiums 140) may be etched more substantially around the contact openings 2102 than conductive structures formed without seams (e.g., in elevationally lower stadiums 140). These material-removal inconsistencies may result in inconsistent oxide regions from the steps 120 of one stadium 140 to the steps 120 of another stadium 140. In contrast, forming the metal oxide regions 122 by oxygen addition, rather than by conductive material removal, may avoid these fabrication inconsistencies, even if some of the conductive structures 106 happen to include seams while others of the conductive structures 106 do not.

In some embodiments, the oxidation process(es) and formation of the metal oxide regions 122, as described herein, may be implemented primarily or only with the steps 120 of elevationally higher stadiums 140 of a given block 116 (FIG. 1), and the steps 120 of elevationally lower stadiums 140 of the block 116 may be otherwise formed, such as by forming the metal oxide regions 122 (or other insulative region(s)) by implementing conventional material-removal (e.g., recessing) and material-formation (e.g., deposition) processes.

In forming the metal oxide regions 122 by the oxidation process(es), the duration and other conditions of the oxidation process(es) may be controlled to ensure the metal oxide regions 122 extend wholly through the thickness of the conductive structures 106 of the step 120 tread, as illustrated in FIG. 23. Though FIG. 23 illustrates the metal oxide region 122 as having substantially vertical sidewalls, the disclosure is not so limited. In other embodiments, the sidewalls of the metal oxide region 122 may taper or bow (e.g., outward, inward) or otherwise vary from vertical.

In some embodiments, a concentration of oxygen in the metal oxide region 122 may vary from the center of the metal oxide region 122 to the periphery of the metal oxide region 122, such as by providing a gradient that lessens with increased diameter. The oxidation process(es) may be controlled (e.g., by duration and/or other conditions) to at least facilitate a sufficient concentration of oxygen in the metal-oxide material of the metal oxide region 122, in the horizontal area through which the through-step contact 130 (FIG. 1) is to extend, to provide a sufficient level of electrical isolation between the conductive material(s) 306 (FIG. 3B) of the through-step contact 130 (FIG. 3B) and the still-conductive material(s) of the conductive structure 106 of the step 120.

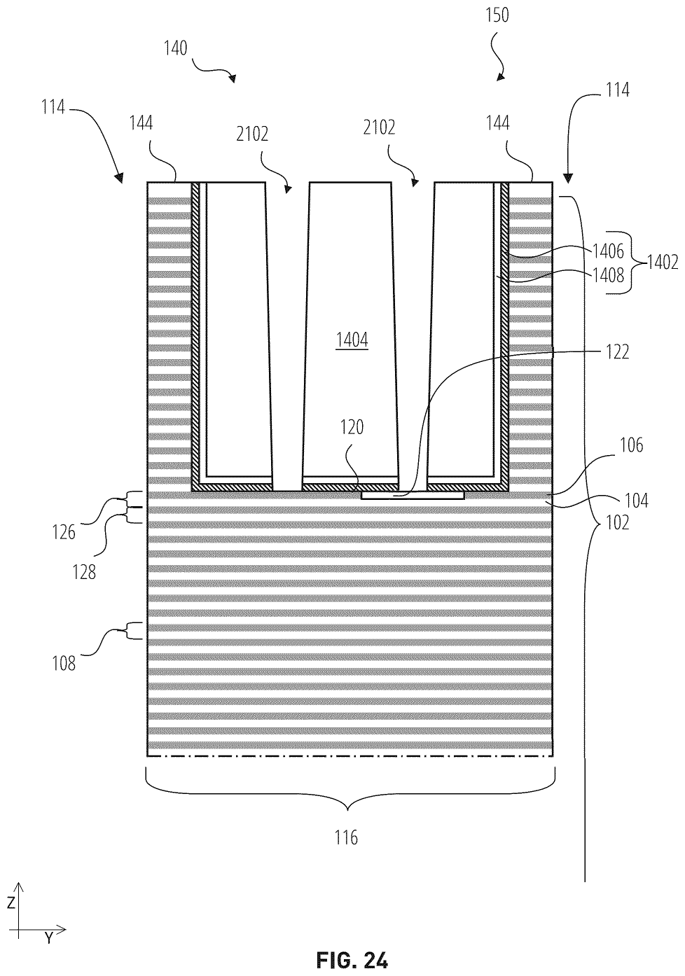

After forming the metal oxide regions 122 in the steps 120 at the base of the still-open contact openings 2102, the sacrificial fill material(s) 2202 may then be removed (e.g., exhumed) from the other contact openings 2102, as illustrated in FIG. 24, to re-expose the portion of the conductive structure 106 of the treaded tier 126 in the contact openings 2102 for the to-step contacts 124 (FIG. 1).

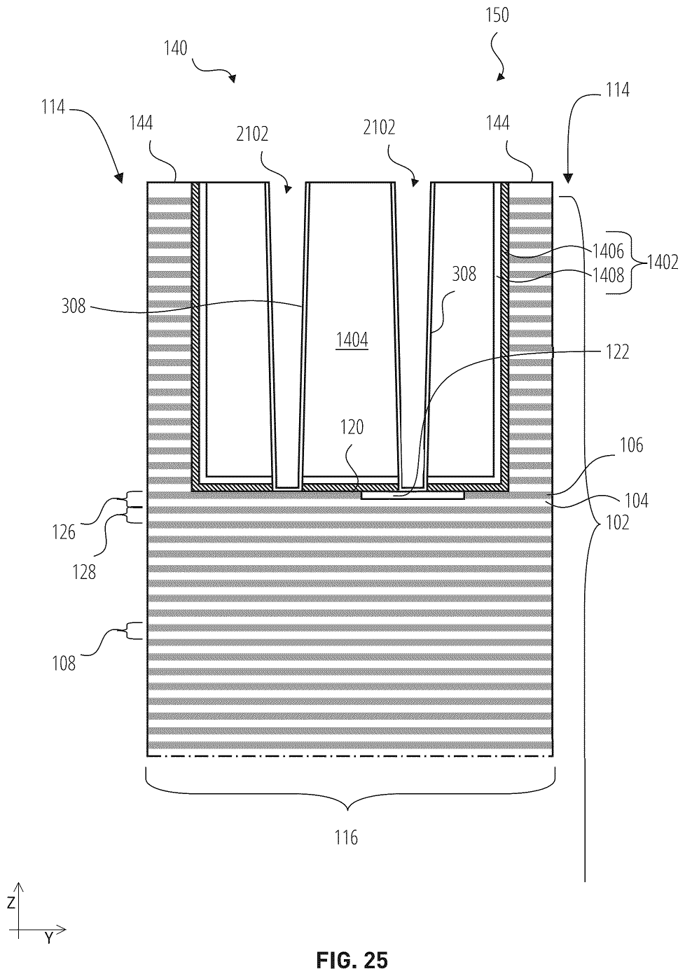

With reference to FIG. 25, at least one contact liner 308 may be formed (e.g., conformally deposited) in each of the contact openings 2102 (for the to-step contacts 124 (FIG. 1)) and in each of the contact openings 2102 (for the through-step contacts 130 (FIG. 1)). In some embodiments, the contact liner 308 may be omitted.

In embodiments in which the contact liner 308 is formed, it may be formed of and include one or more insulative material(s), such as any of the insulative material(s) discussed above for other features. The contact liner 308 may be of minimal thickness (e.g., less than about 10 nm in thickness).

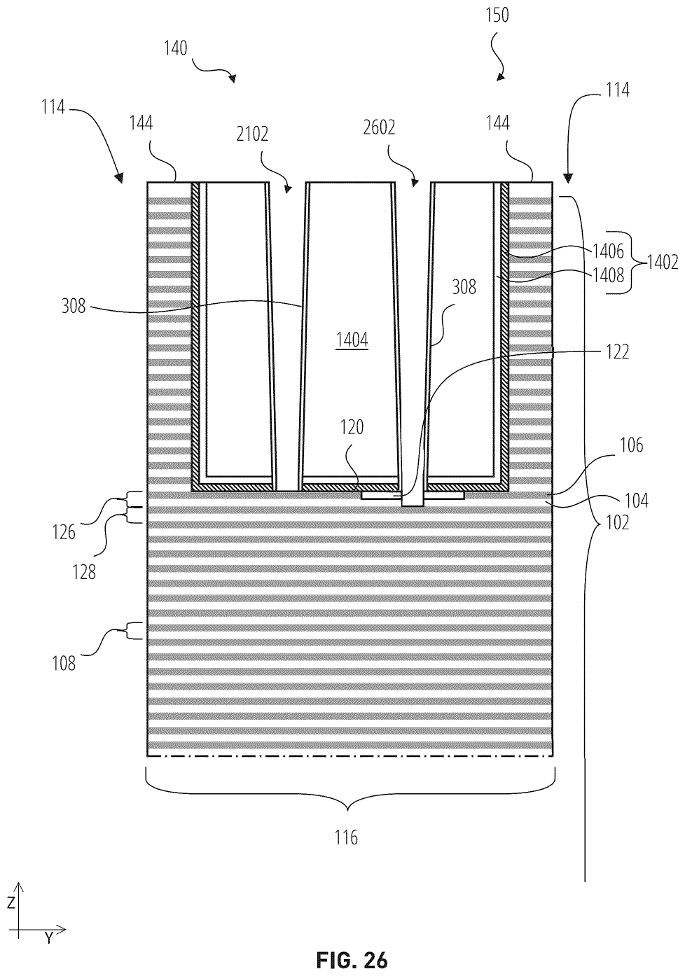

With reference to FIG. 26, the contact liner 308 (if present) may be partially etched (e.g., “punched”) at the base of each contact openings 2102. For a contact opening 2102 for a to-step contact 124 (FIG. 1), the removal of the base of the contact liner 308 exposes a surface area of the conductive structure 106 (at the step 120 tread) of the treaded tier 126. For a contact opening 2102 for a through-step contact 130 (FIG. 1), the removal of the base of the contact liner 308 exposes a surface area of the metal oxide region 122 (at the step 120 tread).

Before, during, or after removing the contact liner 308 from the base of the contact openings 2102, the exposed area of the metal oxide region 122 (in the contact openings 2102 for the through-step contacts 130 (FIG. 1)) is also etched (e.g., punched) to form an extended contact opening 2602 for each through-step contact 130 (FIG. 1). Forming the extended contact openings 2602 exposes a portion of the conductive structure 106 of the covered tier 128 immediately below the treaded tier 126. Each extended contact opening 2602 extends through one of the metal oxide region 122, and therefore also extends through the step 120 tread (e.g., the conductive structure 106 of the treaded tier 126). Each extended contact opening 2602 also extends through the insulative structure 104 of the treaded tier 126.

The metal oxide region 122 may be etched, to form the extended contact opening 2602, using a material-removal process that is selective for metal oxide material(s) relative to metal materials, such that the conductive structure 106 of the treaded tier 126 at the base of the contact opening 2102 for the to-step contact 124 (FIG. 1) remains substantially unetched, and such that the conductive structure 106 of the covered tier 128 at the base of the extended contact opening 2602 for the through-step contact 130 (FIG. 1) remains substantially unetched. For example, etching the metal oxide region 122 may include a dry etch process. In some embodiments, a fluorocarbon chemistry may be used to dry etch metal oxide regions 122 (e.g., metal oxide regions 122 comprising tungsten oxide, molybdenum oxide, and/or another metal oxide) to reduce the metal oxide and remove the oxygen. In such embodiments, the fluorine of the fluorocarbon chemistry may then react with the metal (e.g., the tungsten (W), the molybdenum (W), and/or the other metal) to form volatile compounds that are then removable.

While FIG. 26 illustrates that the metal oxide region 122 has—along the extended contact opening 2602—a substantially vertical sidewall that is substantially coplanar with a sidewall of the contact liner 308 and the insulative structure 104 of the treaded tier 126, the disclosure is not so limited. In other embodiments, the metal oxide region 122 may be recessed from or extend into the extended contact opening 2602, and/or the sidewall of the metal oxide region 122 may be other than substantially vertical.

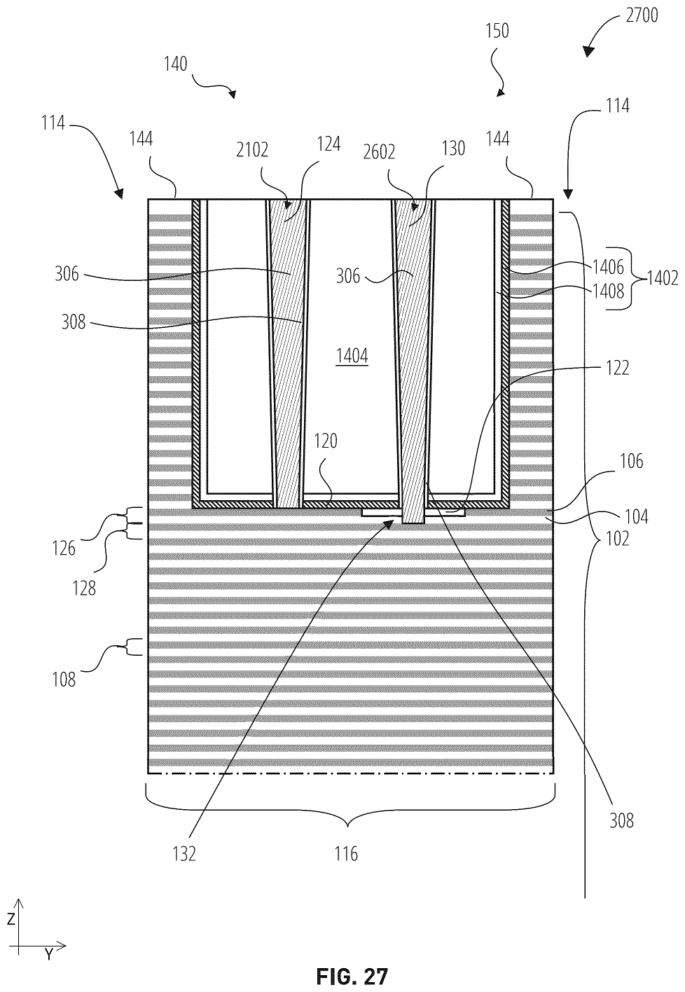

With reference to FIG. 27, conductive material(s) 306 of the line contacts 118 (FIG. 1) may then be formed (e.g., deposited) in the contact openings 2102 and the extended contact openings 2602 to complete the formation of the to-step contacts 124 and the through-step contacts 130.

By this method, the conductive material(s) 306 of the through-step contacts 130 extend through the dielectric liner(s) 1402, through the metal oxide region 122 formed in the step 120 tread, through the insulative structure 104 of the treaded tier 126, and to or into the conductive structure 106 of the covered tier 128.

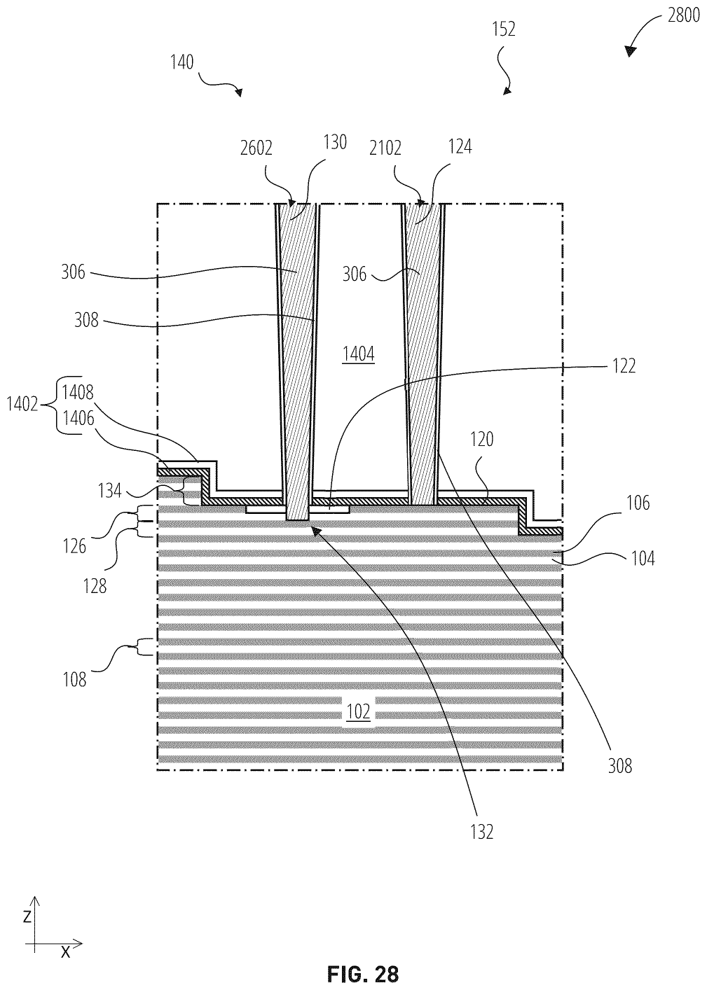

While FIG. 27 illustrates a structure 2700 with the to-step contact 124 and the through-step contact 130 associated with one step 120 of one of the multi-series stadiums 150, forming the to-step contacts 124 and the through-step contacts 130 for the single-series stadiums 152 (FIG. 5) may be substantially the same as described above, but adjusted to correspond to the arrangement of the line contacts 118. For example, rather than forming, for a given step 120, the to-step contact 124 longitudinally adjacent the through-step contact 130 (as in the multi-series stadiums 150), the to-step contact 124 may be formed laterally adjacent the through-step contact 130, as illustrated in FIG. 28, to form a structure 2800 with the steps 120 of the single-series stadiums 152 (FIG. 5). The view of FIG. 28 is taken along section line B-B of FIG. 1 and FIG. 3A.

Accordingly, disclosed is a method of forming a microelectronic device. The method comprises forming a tiered stack over a base structure. The tiered stack comprises a vertically alternating sequence of insulative structures and other structures arranged in tiers. Portions of the tiered stack are removed to form a stadium in the tiered stack. The stadium comprises at least one staircase comprising step treads at ends of some of the tiers of the tiered stack. Each of the step treads is provided by an upper surface portion of one of the other structures of the tiered stack. A portion of each of at least some of the step treads is oxidized to form oxide regions individually extending through one of the at least some of the step treads. Conductive contact structures are formed to extend to one of the step treads. Forming the conductive contact structures comprises forming a first conductive contact structure in physical contact with the one of the step treads and forming a second conductive contact structure extending through the one of the step treads within a horizontal area of one of the oxide regions.

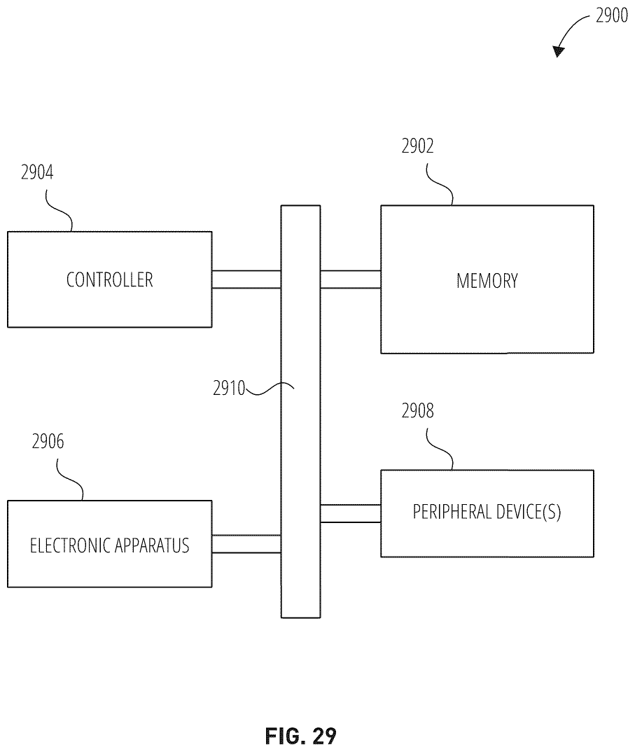

FIG. 29 shows a block diagram of a system 2900, according to embodiments of the disclosure, which system 2900 includes memory 2902 including arrays of vertical strings of memory cells adjacent microelectronic device structure(s) (e.g., microelectronic device structure 100 of FIG. 1 and FIG. 3A; and/or microelectronic device structure 700 of FIG. 7). Therefore, the architecture and structure of the memory 2902 may include one or more device structures according to embodiments of the disclosure and may be fabricated according to one or more of the methods described above (e.g., with reference to FIG. 8 through FIG. 28).

The system 2900 may include a controller 2904 operatively coupled to the memory 2902. The system 2900 may also include another electronic apparatus 2906 and one or more peripheral device(s) 2908. The other electronic apparatus 2906 may, in some embodiments, include one or more of microelectronic device structures (e.g., microelectronic device structure 100 of FIG. 1 and FIG. 3A; and/or microelectronic device structure 700 of FIG. 7), according to embodiments of the disclosure and fabricated according to one or more of the methods described above. One or more of the controller 2904, the memory 2902, the other electronic apparatus 2906, and the peripheral device(s) 2908 may be in the form of one or more integrated circuits (ICs).

A bus 2910 provides electrical conductivity and operable communication between and/or among various components of the system 2900. The bus 2910 may include an address bus, a data bus, and a control bus, each independently configured. Alternatively, the bus 2910 may use conductive lines for providing one or more of address, data, or control, the use of which may be regulated by the controller 2904. The controller 2904 may be in the form of one or more processors.

The other electronic apparatus 2906 may include additional memory (e.g., with one or more microelectronic device structures (e.g., microelectronic device structure 100 of FIG. 1 and FIG. 3A; and/or microelectronic device structure 700 of FIG. 7)), according to embodiments of the disclosure and fabricated according to one or more of the methods described above. Other memory structures of the memory 2902 and/or the other electronic apparatus 2906 may be configured in an architecture other than 3D NAND, such as dynamic random access memory (DRAM), static random access memory (SRAM), synchronous dynamic random access memory (SDRAM), synchronous graphics random access memory (SGRAM), double data rate dynamic ram (DDR), double data rate SDRAM, and/or magnetic-based memory (e.g., spin-transfer torque magnetic RAM (STT-MRAM)).

The peripheral device(s) 2908 may include displays, imaging devices, printing devices, wireless devices, additional storage memory, and/or control devices that may operate in conjunction with the controller 2904.

The system 2900 may include, for example, fiber optics systems or devices, electro-optic systems or devices, optical systems or devices, imaging systems or devices, and information handling systems or devices (e.g., wireless systems or devices, telecommunication systems or devices, and computers).

Any microelectronic device structure included in component(s) of the system 2900 may include one or more of the structures (e.g., structures 2700 and/or 2800 of FIG. 27 and/or FIG. 28, respectively). In one, more, or all such microelectronic device structures, one or more single-series stadium 152 may be otherwise configured as the single-series stadium 152′ of FIG. 6.

Accordingly, disclosed is an electronic system comprising a microelectronic device, at least one processor in operable communication with the microelectronic device, and at least one peripheral device in operable communication with the at least one processor. The microelectronic device comprises a stack structure and a series of staircased stadiums in the stack structure. The stack structure comprises tiers. Each tier includes a conductive structure and an insulative structure vertically adjacent the conductive structure. The series of staircased stadiums comprise steps defined by ends of some of the tiers. The steps of at least one of the staircased stadiums has a riser height of at least two of the tiers and has a tread defined in part by one of the conductive structures and in another part by a metal oxide region extending through the one of the conductive structures. Conductive contact structures extend toward the steps of the at least one of the staircased stadiums. At least some of the conductive contact structures land on treads of the steps of the at least one of the staircased stadiums. At least some others of the conductive contact structures extend through the metal oxide regions of the treads of the steps of the at least one of the staircased stadiums.

While the disclosed structures, apparatus (e.g., devices), systems, and methods are susceptible to various modifications and alternative forms in implementation thereof, specific embodiments have been shown by way of example in the drawings and have been described in detail herein. However, the disclosure is not intended to be limited to the particular forms disclosed. Rather, the disclosure encompasses all modifications, combinations, equivalents, variations, and alternatives falling within the scope of the disclosure as defined by the following appended claims and their legal equivalents.

What is claimed is:

1. A microelectronic device, comprising:
a stack comprising a vertically alternating sequence of insulative structures and conductive structures arranged in tiers;
a staircased stadium within the stack and comprising steps at different tier elevations of a group of the tiers, the steps comprising treads, each of the treads provided by:
an upper surface area of one of the conductive structures within the group of the tiers; and
an upper surface area of a metal oxide region extending through the one of the conductive structures; and
a pair of conductive contact structures extending to one of the steps and comprising:
a first conductive contact structure terminating at the tread of the one of the steps within the upper surface area of the one of the conductive structures; and
a second conductive contact structure extending through the tread of the one of the steps within the upper surface area of the metal oxide region.

2. The microelectronic device of claim 1, wherein the second conductive contact structure further extends through one of the insulative structures.

3. The microelectronic device of claim 2, wherein the one of the insulative structures is directly below the one of the conductive structures.

4. The microelectronic device of claim 1, wherein the second conductive contact structure further extends to a second one of the conductive structures within the group of the tiers.

5. The microelectronic device of claim 4, wherein the second one of the conductive structures does not include an upper surface area providing any of the treads of the steps of the staircased stadium.

6. The microelectronic device of claim 1, further comprising an additional staircased stadium within the stack and comprising additional steps at additional different tier elevations of an additional group of the tiers, the additional steps comprising additional treads, each of the additional treads provided wholly by an upper surface area of one of the conductive structures within the additional group of the tiers.

7. The microelectronic device of claim 6, wherein the additional staircased stadium is elevationally lower than the staircased stadium.

8. The microelectronic device of claim 1, wherein a horizontal dimension of the metal oxide region is at least about two-hundred nanometers.

9. The microelectronic device of claim 1, further comprising, within the staircased stadium:
at least one dielectric liner; and
at least one insulative fill material on the at least one dielectric liner.

10. The microelectronic device of claim 9, wherein the first conductive contact structures and the second conductive contact structure each extend through the at least one insulative fill material and through the at least one dielectric liner.

11. The microelectronic device of claim 1, further comprising at least one insulative liner horizontally around conductive material of the second conductive contact structure.

12. The microelectronic device of claim 11, wherein a lowest end of the at least one insulative liner is above the metal oxide region.

13. The microelectronic device of claim 1, wherein:
the conductive structures comprise at least one metal; and
the metal oxide region comprises the at least one metal and further comprises oxygen.

14. The microelectronic device of claim 1, wherein the steps further comprise risers, at least some of the risers having a height of at least two of the tiers.

15. A microelectronic device, comprising:
a stack structure comprising a vertically alternating sequence of insulative structures and conductive structures arranged in tiers;
a series of stadiums within the stack structure, each of at least some of the stadiums comprising at least one staircase defined in a group of the tiers, the group of the tiers comprising:
treaded tiers, the conductive structures of which provide treads of steps of the at least one staircase; and
covered tiers, the conductive structures of which are each directly vertically below one of the treaded tiers;
metal oxide regions extending through the conductive structures of the treaded tiers;
at least one conductive contact structure extending to one of the conductive structures providing one of the treads; and
at least one other conductive contact structure extending through one of the metal oxide regions, the one of the metal oxide regions being in the one of the conductive structures providing the one of the treads, the at least one other conductive contact structure further extending to one of the conductive structures of the covered tiers.

16. The microelectronic device of claim 15, wherein at least one other of the stadiums comprises at least one other staircase defined in an other group of the tiers, the other group of the tiers consisting of other treaded tiers, the conductive structures of which each provide other treads of other steps of the at least one other staircase, and other metal oxide regions extend through the conductive structures of the other treaded tiers.

17. The microelectronic device of claim 15, wherein the at least one conductive contact structure has a height that is greater than a height of the at least one conductive contact structure.

18. The microelectronic device of claim 15, wherein:
the conductive structures comprise at least one of tungsten, titanium, cobalt, and ruthenium; and
the metal oxide regions comprise at least one tungsten oxide, titanium oxide, cobalt oxide, and non-conductive ruthenium oxide.

19. The microelectronic device of claim 15, wherein:
the conductive structures comprise a metal nitride material; and
the metal oxide regions comprise a metal oxynitride material.

20. A method of forming a microelectronic device, the method comprising:
forming a tiered stack over a base structure, the tiered stack comprising a vertically alternating sequence of insulative structures and other structures arranged in tiers;
removing portions of the tiered stack to form a stadium in the tiered stack, the stadium comprising at least one staircase comprising step treads at ends of some of the tiers of the tiered stack, each of the step treads provided by an upper surface portion of one of the other structures of the tiered stack;
oxidizing a portion of each of at least some of the step treads to form oxide regions individually extending through one of the at least some of the step treads; and
forming conductive contact structures extending to one of the step treads, comprising:
forming a first conductive contact structure in physical contact with the one of the step treads; and
forming a second conductive contact structure extending through the one of the step treads within a horizontal area of one the oxide regions.

21. The method of claim 20, further comprising, before oxidizing the portion of the each of the at least some of the step treads:
forming at least one dielectric fill material in a stadium opening above the stadium;
replacing the other structures with conductive structures so that the each of the step treads is provided by an upper surface portion of one of the conductive structures; and
forming contact openings extending through the at least one dielectric fill material.

22. The method of claim 21, wherein oxidizing the portion of the each of the at least one of the step treads comprises adding oxygen to a region of the one of the conductive structures at a base of one of the contact openings to form a metal oxide region extending through the one of the conductive structures.

23. The method of claim 21, wherein the method does not comprise, after forming the conductive structures in place of the other structures and before forming the oxide regions, removing any portion of the conductive structures.

24. The method of claim 20, further comprising, after the oxidizing and before forming the conductive contact structures, removing a portion of the one of the oxide regions and removing a portion of one of the insulative structures below the one of the oxide regions to form an opening extending through the one of the oxide regions and through the one of the insulative structures.

25. An electronic system, comprising:
a microelectronic device comprising:
a stack structure comprising tiers each including a conductive structure and an insulative structure vertically adjacent the conductive structure;
a series of staircased stadiums in the stack structure and comprising steps defined by ends of some of the tiers, the steps of at least one of the staircased stadiums having:
a riser height of at least two of the tiers; and
a tread defined in part by one of the conductive structures and in another part by a metal oxide region extending through the one of the conductive structures; and
conductive contact structures extending toward the steps of the at least one of the staircased stadiums, at least some of the conductive contact structures landing on treads of the steps of the at least one of the staircased stadiums, at least some others of the conductive contact structures extending through the metal oxide regions of the treads of the steps of the at least one of the staircased stadiums;
at least one processor in operable communication with the microelectronic device; and
at least one peripheral device in operable communication with the at least one processor.
